(19) United States
(12) Patent Application Publication
(10) Pub. No.: US 2023/0138754 A1
(43) Pub. Date: May 4, 2023

(54) LIGHT EMITTING ELEMENT

(71) Applicant: Samsung Display Co., Ltd., Yongin-si (KR)

(72) Inventors: JIYOUNG LEE, Hwaseong-si (KR); TSUYOSHI NAIJO, Suwon-si (KR); JANG YEOL BAEK, Yongin-si (KR); HYOSUP SHIN, Hwaseong-si (KR)

(73) Assignee: Samsung Display Co., Ltd., Yongin-si (KR)

(21) Appl. No.: 17/857,616

(22) Filed: Jul. 5, 2022

(30) Foreign Application Priority Data
Oct. 1, 2021 (KR) 10-2021-0131041

(51) Int. Cl. H01L 51/50; H01L 51/00

(52) U.S. Cl. CPC H01L 51/5024; H01L 51/008; H01L 51/0059; H01L 51/0054; H01L 51/0087; H01L 51/009; H01L 51/0072; H01L 51/0094; H01L 51/0067; H01L 51/5072; H01L 51/5056; H01L 51/5028; H01L 2251/5384

(57) ABSTRACT

A light emitting element includes a first electrode, a second electrode disposed on the first electrode, and an emission layer disposed between the first electrode and the second electrode. The emission layer includes a hole transporting host, an electron transporting host, a phosphorescent sensitizer, and a fluorescent dopant, wherein the fluorescent dopant emits light having a full width at half maximum (FWHM) equal to or less than about 20 nm. The fluorescent dopant may include a compound represented by Formula 1. Accordingly, the light emitting element according to an embodiment may exhibit enhanced color purity and long service life characteristics.

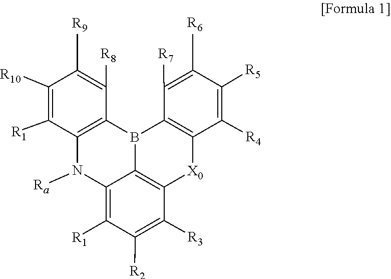

### CROSS-REFERENCE TO RELATED APPLICATION(S)

This application claims priority to and benefits of Korean Patent Application No. 10-2021-0131041 under 35 U.S.C. § 119, filed on Oct. 1, 2021 in the Korean Intellectual Property Office, the entire contents of which are incorporated herein by reference.

### BACKGROUND

### 1. Technical Field

The disclosure relates to a light emitting element including a fluorescent dopant.

### 2. Description of the Related Art

Active development continues for organic electroluminescence display devices and the like as image display devices. Organic electroluminescence display devices are display devices including so-called self-luminescent light emitting elements in which holes and electrons respectively injected from a first electrode and a second electrode recombine in an emission layer, so that a luminescent material in the emission layer emits light to achieve display.

In the application of light emitting elements to display devices, there is a demand for light emitting elements with a long service life, and continuous development is required for light emitting elements which are capable of stably achieving such characteristics.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element exhibiting enhanced color purity and long service life characteristics.

An embodiment provides a light emitting element which may include a first electrode, a second electrode disposed on the first electrode, and an emission layer disposed between the first electrode and the second electrode. The emission layer may include a hole transporting host, an electron transporting host, a phosphorescent sensitizer, and a fluorescent dopant, and the fluorescent dopant may emit light having a full width at half maximum (FWHM) equal to or less than about 20 nm.

In an embodiment, the fluorescent dopant may have a difference in a range of about 0.4 eV to about 1.0 eV between a singlet state energy level and a triplet state energy level.

In an embodiment, the emission layer may emit fluorescent light.

In an embodiment, the fluorescent dopant may have an absolute value in a range of about 1.9 eV to about 2.2 eV of a triplet state energy level.

In an embodiment, the hole transporting host and the electron transporting host may form an exciplex.

In an embodiment, the exciplex may have a greater triplet state energy level than the phosphorescent sensitizer, and the phosphorescent sensitizer may have a greater triplet state energy level than the fluorescent dopant.

In an embodiment, the fluorescent dopant may include a compound represented by Formula 1.

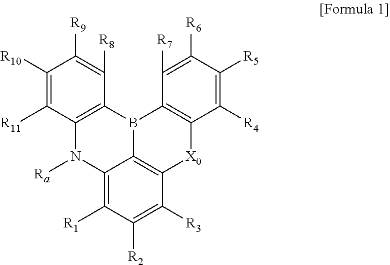

In Formula 1, X₀ may be N(R_{b}) or S; Rₐ and R_{b} may each independently be a substituted or unsubstituted aryl group having 6 to 20 ring-forming carbon atoms; R₁ to R₁₁ may each independently be a hydrogen atom, a substituted or unsubstituted amine group, or a substituted or unsubstituted aryl group having 6 to 30 ring-forming carbon atoms; and at least one of R₁ to R₁₁ may include a substituted or unsubstituted aryl group having 10 to 30 ring-forming carbon atoms.

In an embodiment, the fluorescent dopant may be a multiple resonance (MR) type fluorescent dopant.

In an embodiment, the emission layer may include an amount of the fluorescent dopant in a range of about 0.4 vol % to about 0.8 vol %, with respect to a total volume of the hole transporting host, the electron transporting host, the phosphorescent sensitizer, and the fluorescent dopant.

In an embodiment, the light emitting element may further include a hole transport region disposed between the first electrode and the emission layer, and an electron transport region disposed between the emission layer and the second electrode.

In an embodiment, the fluorescent dopant may include one selected from Compound Group 1, which is explained below.

In an embodiment, the phosphorescent sensitizer may include one selected from Compound Group 2, which is explained below.

In an embodiment, the hole transporting host may include one selected from Compound Group 3, which is explained below.

In an embodiment, the electron transporting host may include one selected from Compound Group 4, which is explained below.

In an embodiment, a light emitting element may include a first electrode, a second electrode disposed on the first electrode, and an emission layer disposed between the first electrode and the second electrode. The emission layer may include a hole transporting host, an electron transporting host, a phosphorescent sensitizer, and a fluorescent dopant, wherein the fluorescent dopant may emit light having a full width at half maximum (FWHM) equal to or less than about 20 nm, and the fluorescent dopant may include a compound represented by Formula 1.

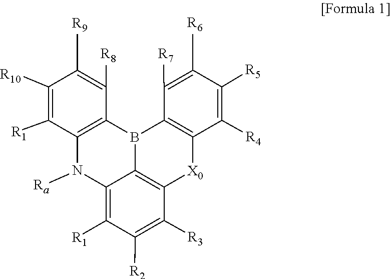

In Formula 1, X₀ may be N(R_{b}) or S; Rₐ and R_{b} may each independently be a substituted or unsubstituted aryl group having 6 to 20 ring-forming carbon atoms; R₁ to R₁₁ may each independently be a hydrogen atom, a substituted or unsubstituted amine group, or a substituted or unsubstituted aryl group having 6 to 30 ring-forming carbon atoms; and at least one of R₁ to R₁₁ may include a substituted or unsubstituted aryl group having 10 to 30 ring-forming carbon atoms.

In an embodiment, the fluorescent dopant may have a difference in a range of about 0.4 eV to about 1.0 eV between a singlet state energy level and a triplet state energy level.

In an embodiment, the hole transporting host and the electron transporting host may form an exciplex, the exciplex may have a greater triplet state energy level than the phosphorescent sensitizer, and the phosphorescent sensitizer may have a greater triplet state energy level than the fluorescent dopant.

In an embodiment, the fluorescent dopant may have an absolute value in a range of about 1.9 eV to about 2.2 eV of a triplet state energy level.

In an embodiment, the hole transporting host may include a carbazole compound represented by Formula 2.

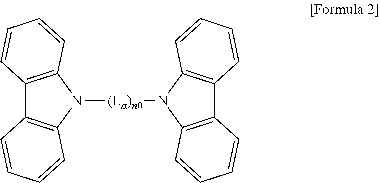

In Formula 2, n0 may be 1 or 2; and Lₐ may be a substituted or unsubstituted arylene group having 6 to 20 ring-forming carbon atoms.

In an embodiment, the electron transporting host may include a triazine compound represented by Formula 3.

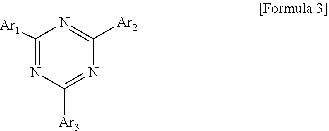

In Formula 3, Ar₁ to Ar₃ may each independently be a substituted or unsubstituted aryl group having 6 to 20 ring-forming carbon atoms, or a substituted or unsubstituted heteroaryl group having 2 to 20 ring-forming carbon atoms.

### BRIEF DESCRIPTION OF THE DRAWINGS

The accompanying drawings are included to provide a further understanding of the embodiments, and are incorporated in and constitute a part of this specification. The drawings illustrate embodiments of disclosure and principles thereof. The above and other aspects and features of the disclosure will become more apparent by describing in detail embodiments thereof with reference to the attached drawings, in which:

FIG. 1 is a plan view showing a display device according to an embodiment;

FIG. 2 is a schematic cross-sectional view showing a portion corresponding to line I-I′ of FIG. 1;

FIG. 3 is a schematic cross-sectional view showing a light emitting element according to an embodiment;

FIG. 4 is a schematic cross-sectional view showing a light emitting element according to an embodiment;

FIG. 5 is a schematic cross-sectional view showing a light emitting element according to an embodiment;

FIG. 6 is a schematic cross-sectional view showing a light emitting element according to an embodiment;

FIG. 7 shows a band diagram of a light emitting element according to an embodiment;

FIG. 8 is a graph showing changes in photoluminescence intensity over time in light emitting elements of Comparative Examples and Examples;

FIG. 9 is a schematic cross-sectional view showing a display device according to an embodiment;

FIG. 10 is a schematic cross-sectional view showing a display device according to an embodiment;

FIG. 11 is a schematic cross-sectional view showing a display device according to an embodiment; and

FIG. 12 is a schematic cross-sectional view showing a display device according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

The term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, a light emitting element according to an embodiment will be described with reference to the drawings.

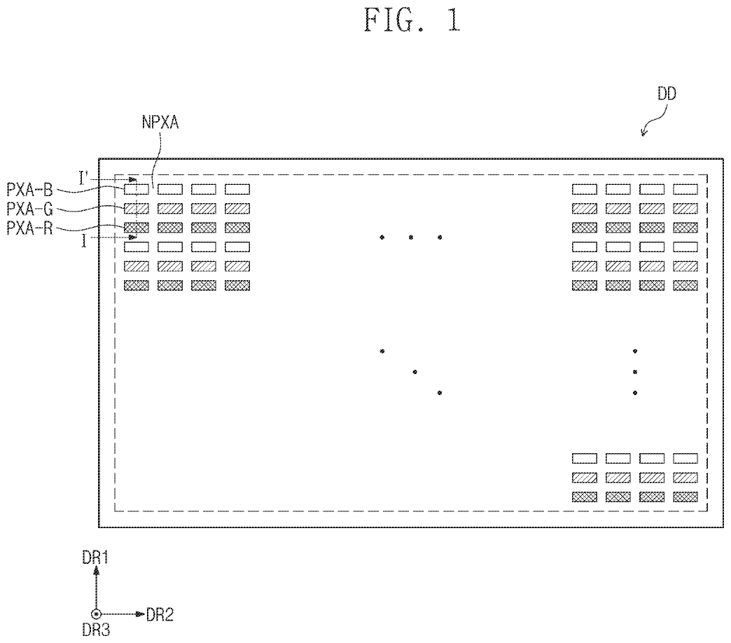

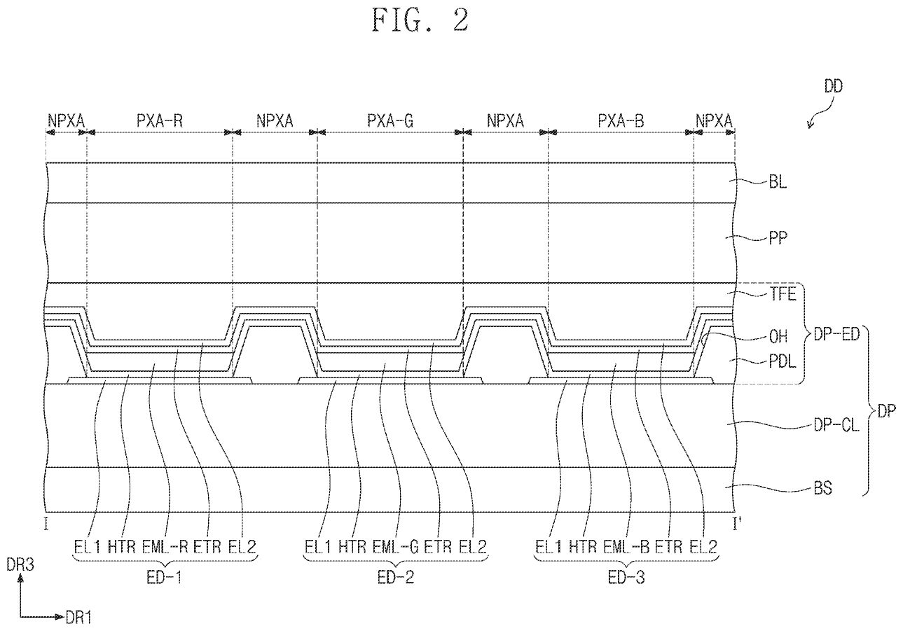

FIG. 1 is a plan view of a display device DD according to an embodiment. FIG. 2 is a schematic cross-sectional view of a display device DD according to an embodiment. FIG. 2 is a schematic cross-sectional view showing a portion corresponding to line I-I′ of FIG. 1.

The display device DD may include a display panel DP and an optical layer PP disposed on the display panel DP. The display panel DP may include light emitting elements ED-1, ED-2, and ED-3. The display device DD may include multiples of each of the light emitting elements ED-1, ED-2, and ED-3. The optical layer PP may be disposed on the display panel DP and may control light reflected at the display panel DP from an external light. The optical layer PP may include, for example, a polarizing layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic resin, a silicone-based resin, or an epoxy-based resin.

The display panel DP may include a base layer BS, a circuit layer DP-CL provided on the base layer BS, and a display element layer DP-ED. The display element layer DP-ED may include pixel defining films PDL, light emitting elements ED-1, ED-2, and ED-3 disposed between the pixel defining films PDL, and an encapsulation layer TFE disposed on the light emitting elements ED-1, ED-2, and ED-3.

The base layer BS may provide a base surface in which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL may be disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

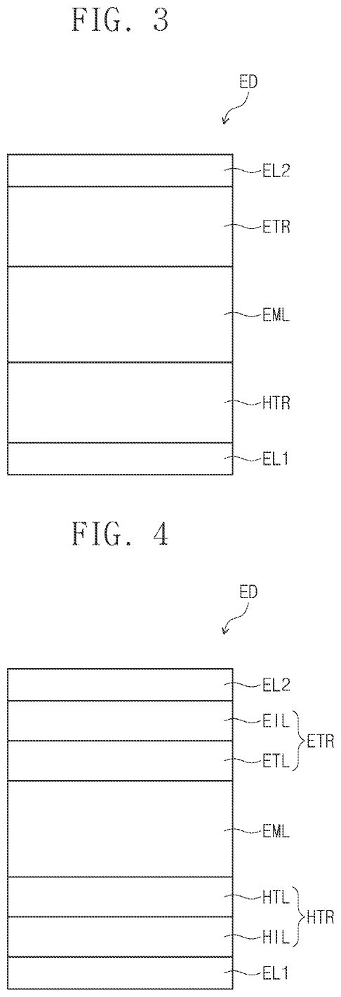

The light emitting elements ED-1, ED-2, and ED-3 may each have a structure of a light emitting element ED of an embodiment according to FIGS. 3 to 6, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 shows an embodiment in which the emission layers EML-R, EML-G, and EML-B of the light emitting elements ED-1, ED-2, and ED-3 are disposed in openings OH defined in the pixel defining films PDL, and the hole transport region HTR, the electron transport region ETR, and the second electrode EL2 are each provided as a common layer for all of the light emitting elements ED-1, ED-2, and ED-3. However, embodiments are not limited thereto. Although not shown in FIG. 2, in an embodiment, the hole transport region HTR and the electron transport region ETR may each be patterned inside the openings OH defined in the pixel defining films PDL and provided. For example, in an embodiment, the hole transport region HTR, the emission layers EML-R, EML-G, and EML-B, and the electron transport region ETR, etc., of the light emitting elements ED-1, ED-2, and ED-3 may each be patterned and provided through an inkjet printing method.

An encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be a single layer or a stack of multiple layers. The encapsulation layer may include at least one insulating layer. The encapsulation layer TFE according to an embodiment may include at least one inorganic film (hereinafter, an encapsulation inorganic film). The encapsulation layer TFE according to an embodiment may include at least one organic film (hereinafter, an encapsulation organic film) and at least one encapsulation inorganic film.

The encapsulation inorganic film may protect the display element layer DP-ED from moisture and/or oxygen, and the encapsulation organic film may protect the display element layer DP-ED from foreign substances such as dust particles. The encapsulation inorganic film may include silicon nitride, silicon oxy nitride, silicon oxide, titanium oxide, aluminum oxide, etc., but is not particularly limited thereto. The encapsulation organic layer may include an acrylic compound, an epoxy-based compound, etc. The encapsulation organic layer may include a photopolymerizable organic material, and is not particularly limited.

The encapsulation layer TFE may be disposed on the second electrode EL2, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from each of the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. For example, in an embodiment, the light emitting regions PXA-R, PXA-G, and PXA-B may each correspond to a pixel. The pixel defining films PDL may separate the light emitting elements ED-1, ED-2, and ED-3. The emission layers EML-R, EML-G, and EML-B of the light emitting elements ED-1, ED-2 and ED-3 may be disposed in openings OH defined by the pixel defining films PDL and separated from each other.

The light emitting regions PXA-R, PXA-G, and PXA-B may be divided into groups according to the color of light generated from the light emitting elements ED-1, ED-2, and ED-3. In the display device DD of an embodiment shown in FIGS. 1 and 2, three light emitting regions PXA-R, PXA-G, and PXA-B which emit red light, green light, and blue light, are illustrated as an example. For example, the display device DD of an embodiment may include a red light emitting region PXA-R, a green light emitting region PXA-G, and a blue light emitting region PXA-B, which are distinct from one another.

In the display device DD according to an embodiment, the light emitting elements ED-1, ED-2, and ED-3 may emit light having different wavelength ranges. For example, in an embodiment, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range or at least one thereof may emit light in a different wavelength range. For example, the first to third light emitting elements ED-1, ED-2, and ED-3 may all emit blue light.

The light emitting regions PXA-R, PXA-G, and PXA-B in the display device DD according to an embodiment may be arranged in a stripe configuration. Referring to FIG. 1, red light emitting regions PXA-R, green light emitting regions PXA-G, and blue light emitting regions PXA-B may each be arranged along a second directional axis DR2. In another embodiment, the red light emitting region PXA-R, the green light emitting region PXA-G, and the blue light emitting region PXA-B may be alternately arranged in turn along a first directional axis DR1.

FIGS. 1 and 2 illustrate that the light emitting regions PXA-R, PXA-G, and PXA-B are all similar in size, but embodiments are not limited thereto, and the light emitting regions PXA-R, PXA-G and PXA-B may be different in size from each other according to a wavelength range of emitted light. The areas of the light emitting regions PXA-R, PXA-G, and PXA-B may be areas in a plan view that are defined by the first directional axis DR1 and the second directional axis DR2.

The arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged may be provided in various combination according to the display quality characteristics which are required for the display device DD. For example, the light emitting regions PXA-R, PXA-G, and PXA-B may be arranged in a PENTILE® configuration or a diamond configuration.

In an embodiment, areas of each of the light emitting regions PXA-R, PXA-G, and PXA-B may be different in size from one another. For example, in an embodiment, a green light emitting region PXA-G may be smaller than a blue light emitting region PXA-B in size, but embodiments are not limited thereto.

Hereinafter, FIGS. 3 to 6 are schematic cross-sectional views showing a light emitting element according to an embodiment. The light emitting element ED according to an embodiment may include a first electrode ELL a hole transport region HTR, an emission layer EML, an electron transport region ETR, and a second electrode EL2.

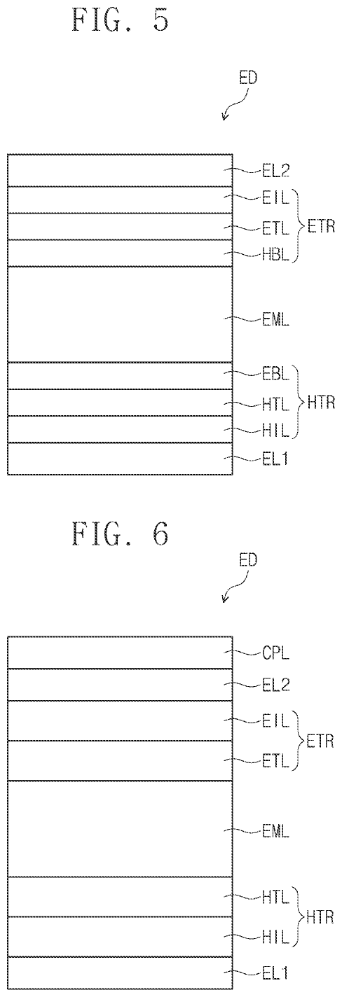

In comparison to FIG. 3, FIG. 4 shows a schematic cross-sectional view of a light emitting element ED of an embodiment in which the hole transport region HTR includes a hole injection layer HIL and a hole transport layer HTL, and the electron transport region ETR includes an electron injection layer EIL and an electron transport layer ETL. In comparison to FIG. 3, FIG. 5 shows a schematic cross-sectional view of a light emitting element ED of an embodiment in which the hole transport region HTR includes a hole injection layer HIL, a hole transport layer HTL, and an electron blocking layer EBL, and the electron transport region ETR includes an electron injection layer EIL, an electron transport layer ETL, and a hole blocking layer HBL. In comparison to FIG. 4, FIG. 6 shows a schematic cross-sectional view of a light emitting element ED of an embodiment, in which a capping layer CPL disposed on the second electrode EL2 is provided.

In the light emitting element ED according to an embodiment, the emission layer EML may include a hole transporting host, an electron transporting host, a phosphorescent sensitizer, and a fluorescent dopant. In an embodiment, the fluorescent dopant of the emission layer EML may emit light having a full width at half maximum (FWHM) equal to or less than about 20 nm. The light emitting element ED according to an embodiment including the fluorescent dopant that emits light having a full width at half maximum equal to or less than about 20 nm may exhibit enhanced color purity of light. The fluorescent dopant may include an aryl group having 10 to 30 ring-forming carbon atoms, which is bonded to a pentacyclic condensed ring that may include at least one nitrogen atom and one boron atom as ring-forming atoms. The aryl group having 10 to 30 ring-forming carbon atoms may be substituted or unsubstituted.

In the description, the term “substituted or unsubstituted” may mean a group that is substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, an alkoxy group, a hydrocarbon ring group, an aryl group, and a heterocyclic group. Each of the substituents listed above may itself be substituted or unsubstituted. For example, a biphenyl group may be interpreted as an aryl group or may be interpreted as a phenyl group substituted with a phenyl group.

In the description, an alkyl group may be a linear, a branched, or a cyclic type. The number of carbon atoms in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, etc., but are not limited thereto.

In the description, an aryl group may be any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but are not limited thereto.

In the description, a heteroaryl group may include at least one of B, O, N, P, Si, or S as a heteroatom. When the heteroaryl group contains two or more heteroatoms, the two or more heteroatoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but are not limited thereto.

In the description, the above description of the aryl group may be applied to an arylene group, except that the arylene group is a divalent group. The above description of the heteroaryl group may be applied to a heteroarylene group, except that the heteroarylene group is a divalent group.

In the description, the number of carbon atoms in an amine group is not particularly limited, but may be 1 to 30. The amine group may be an alkyl amine group or an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but are not limited thereto.

In the description, a direct linkage may be a single bond.

In the description, [symbol] and [symbol] each represents a bonding position to a neighboring atom.

In an embodiment, the fluorescent dopant may include a compound represented by Formula 1. The emission layer EML may include a fluorescent dopant compound represented by Formula 1. In Formula 1, a pentacyclic condensed ring including at least one nitrogen atom and one boron atom as ring-forming atoms may exhibit multiple resonance characteristics.

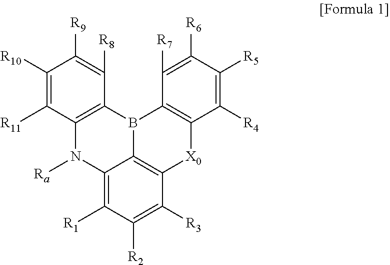

In Formula 1, X₀ may be N(R_{b}) or S. In Formula 1, Rₐ and R_{b} may each independently be a substituted or unsubstituted aryl group having 6 to 20 ring-forming carbon atoms. For example, Rₐ and R_{b} may each independently be a substituted or unsubstituted phenyl group.

In Formula 1, R₁ to R₁₁ may each independently be a hydrogen atom, a substituted or unsubstituted amine group, or a substituted or unsubstituted aryl group having 6 to 30 ring-forming carbon atoms. In Formula 1, at least one of R₁ to R₁₁ may include a substituted or unsubstituted aryl group having 10 to 30 ring-forming carbon atoms. A fluorescent dopant including the substituted or unsubstituted aryl group having 10 to 30 ring-forming carbon atoms may exhibit a characteristic of having a lower triplet state energy level than a singlet state energy level. The substituted or unsubstituted aryl group having 10 to 30 ring-forming carbon atoms corresponds to a bulky substituent, and the bulky substituent may lower the triplet state energy level of the fluorescent dopant.

For example, at least one of R₁ to R₁₁ may include a polycyclic aryl group, and the polycyclic aryl group may be in a form in which three or more aryl groups are condensed. In an embodiment, any one of R₂, R₅, or R₁₀ may each independently include a substituted or unsubstituted pyrenyl group, and the pyrenyl group may be bonded to an amine group and connected to a pentacyclic condensed ring including at least one nitrogen atom and one boron atom. However, this is presented as an example, and the bonding position and bonding form of the polycyclic aryl group are not limited thereto.

In comparison to a compound which does not include a polycyclic aryl group as a substituent for a pentacyclic condensed ring containing at least one nitrogen atom and one boron atom as ring-forming atoms, the fluorescent dopant including a polycyclic aryl group in which three or more aryl groups are condensed may have a lower triplet state energy level than a singlet state energy level. The polycyclic aryl group in which three or more aryl groups are condensed may correspond to a bulky substituent. The fluorescent dopant including the polycyclic aryl group in which three or more aryl groups are condensed may exhibit a characteristic of having a low triplet state energy level. The fluorescent dopant including the polycyclic aryl group in which three or more aryl groups are condensed may have a difference equal to or greater than about 0.4 eV between a singlet state energy level and a triplet state energy level.

For example, in the fluorescent dopant including a pyrenyl group, the triplet state energy level may be lower than the singlet state energy level by about 0.4 eV to about 1.0 eV. The pyrenyl group has a characteristic of having a lower energy level in the triplet state than in the singlet state, and the fluorescent dopant including the pyrenyl group may exhibit a characteristic of having a lower triplet state energy level than the singlet state energy level. Accordingly, in an embodiment, the fluorescent dopant including a polycyclic aryl group in which three or more aryl groups are condensed may exhibit a characteristic of having a lower triplet state energy level than a singlet state energy level by about 0.4 eV to about 1.0 eV.

The fluorescent dopant may have a difference in a range of about 0.4 eV to about 1.0 eV between a singlet state energy level and a triplet state energy level. The light emitting element ED of an embodiment including the fluorescent dopant having a difference in a range of about 0.4 eV to about 1.0 eV between a singlet state energy level and a triplet state energy level may exhibit enhanced service life characteristics.

The fluorescent dopant included in the emission layer EML may have an absolute value in a range of about 1.9 eV to about 2.2 eV of a triplet state energy level. For example, the fluorescent dopant may have an absolute value in a range of about 2.0 eV to about 2.1 eV of a triplet state energy level. However, this is only presented as an example, and in the fluorescent dopant, the triplet state energy level may be lower than the singlet state energy level by about 0.4 eV to about 1.0 eV.

The emission layer EML may include a multiple resonance (MR) type fluorescent dopant. The MR-type fluorescent dopant may emit light having a small full width at half maximum. The emission layer EML may not include a donor-acceptor (DA) type fluorescent dopant that exhibits a large full width at half maximum. In an embodiment, the emission layer EML including the MR-type fluorescent dopant emits light having a full width at half maximum equal to or less than about 20 nm, and the light emitting element ED according to an embodiment may exhibit excellent color purity.

For example, the fluorescent dopant may have a difference in a range of about 12 nm to about 14 nm in maximum wavelength between when absorbing energy and when emitting energy. For example, a difference in wavelength according to stokes shift in the fluorescent dopant may be in a range of about 12 nm to about 14 nm.

The fluorescent dopant may include any one selected from Compound Group 1. The emission layer EML may include any one selected from Compound Group 1.

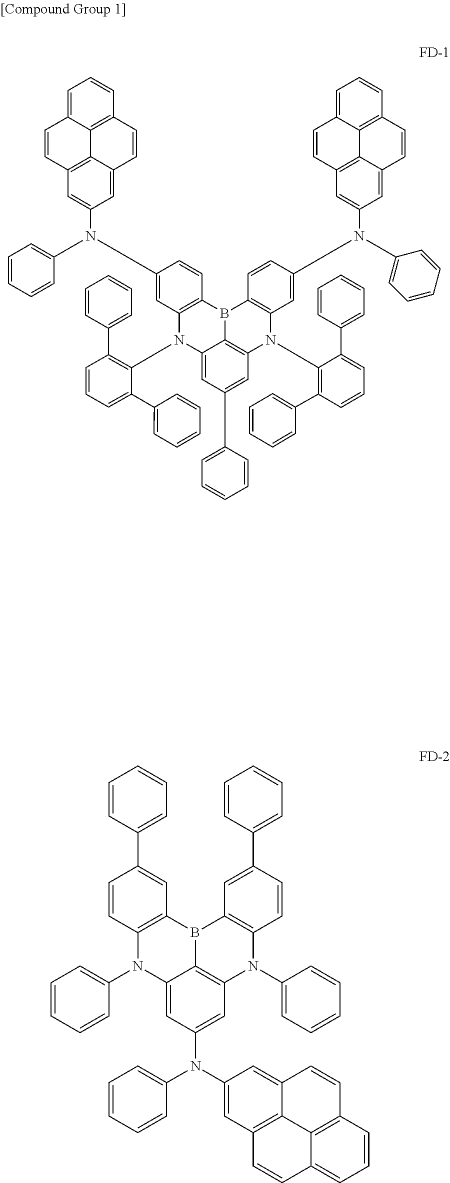 [SMILES: c1ccc(-c2cc3c4c(c2)N(c2c(-c5ccccc5)cccc2-c2ccccc2)c2cc(N(c5ccccc5)c5cc6ccc7cccc8ccc(c5)c6c78)ccc2B4c2ccc(N(c4ccccc4)c4cc5ccc6cccc7ccc(c4)c5c67)cc2N3c2c(-c3ccccc3)cccc2-c2ccccc2)cc1 ; c1ccc(-c2ccc3c(c2)B2c4cc(-c5ccccc5)ccc4N(c4ccccc4)c4cc(N(c5ccccc5)c5cc6ccc7cccc8ccc(c5)c6c78)cc(c42)N3c2ccccc2)cc1]

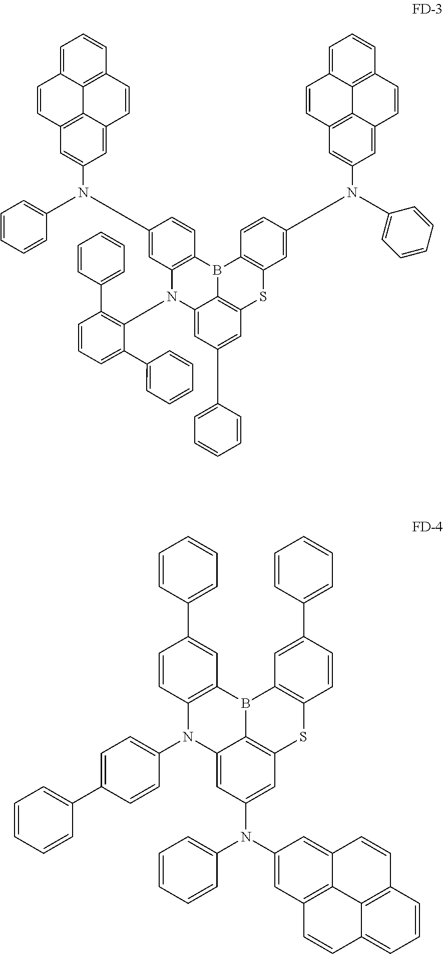 [SMILES: c1ccc(-c2cc3c4c(c2)N(c2c(-c5ccccc5)cccc2-c2ccccc2)c2cc(N(c5ccccc5)c5cc6ccc7cccc8ccc(c5)c6c78)ccc2B4c2ccc(N(c4ccccc4)c4cc5ccc6cccc7ccc(c4)c5c67)cc2S3)cc1 ; c1ccc(-c2ccc(N3c4ccc(-c5ccccc5)cc4B4c5cc(-c6ccccc6)ccc5Sc5cc(N(c6ccccc6)c6cc7ccc8cccc9ccc(c6)c7c89)cc3c54)cc2)cc1]

In the emission layer EML, with respect to a total volume of the hole transporting host, the electron transporting host, the phosphorescent sensitizer, and the fluorescent dopant, an amount of the fluorescent dopant may be in a range of about 0.4 vol % to about 0.8 vol %. The emission layer EML including the fluorescent dopant in an amount of about less than 0.4 vol % or greater than 0.8 vol %, with respect to a total volume of the hole transporting host, the electron transporting host, the phosphorescent sensitizer, and the fluorescent dopant, may fail to exhibit enhanced light emitting characteristics because fluorescent light emission efficiency is reduced or because the fluorescent dopant does not successfully emit light and decays. Accordingly, the light emitting element ED according to an embodiment including the fluorescent dopant in an amount of about 0.4 vol % to 0.8 vol %, with respect to a total volume of the hole transporting host, the electron transporting host, the phosphorescent sensitizer, and the fluorescent dopant, may exhibit satisfactory light emitting characteristics.

The emission layer EML may include a phosphorescent sensitizer. In the emission layer EML, the phosphorescent sensitizer may be included at a larger volume than the fluorescent dopant. For example, the emission layer EML may include the phosphorescent sensitizer at an amount of about 13.0 vol % with respect to a total volume of the hole transporting host, the electron transporting host, the phosphorescent sensitizer, and the fluorescent dopant. However, this is presented as an example, and the volume of the phosphorescent sensitizer included in the emission layer EML is not limited thereto.

In an embodiment, the phosphorescent sensitizer may include any one selected from Compound Group 2. The emission layer EML may include any one selected from Compound Group 2 as the phosphorescent sensitizer.

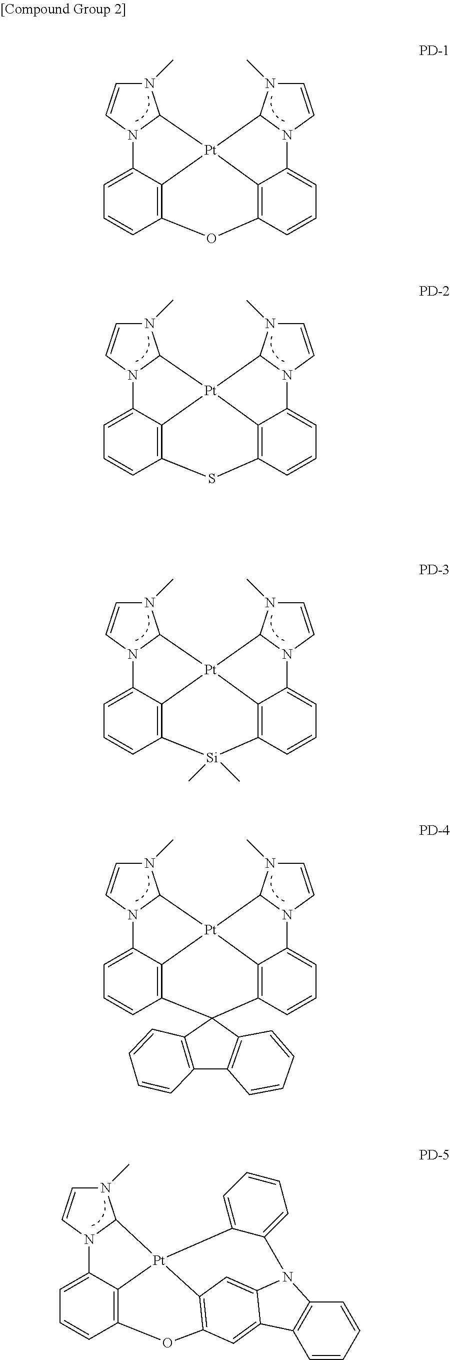

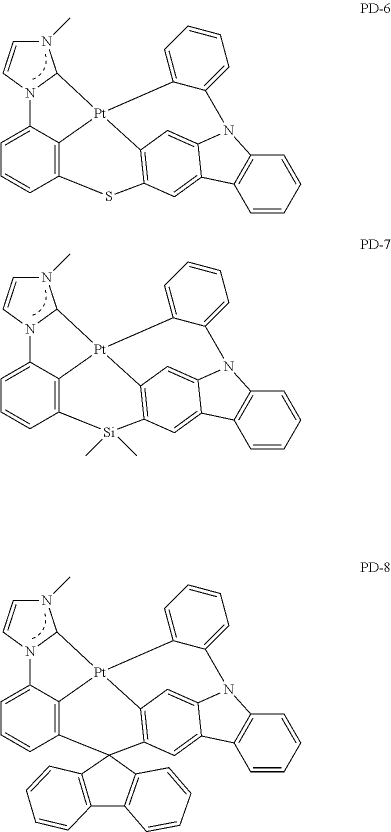

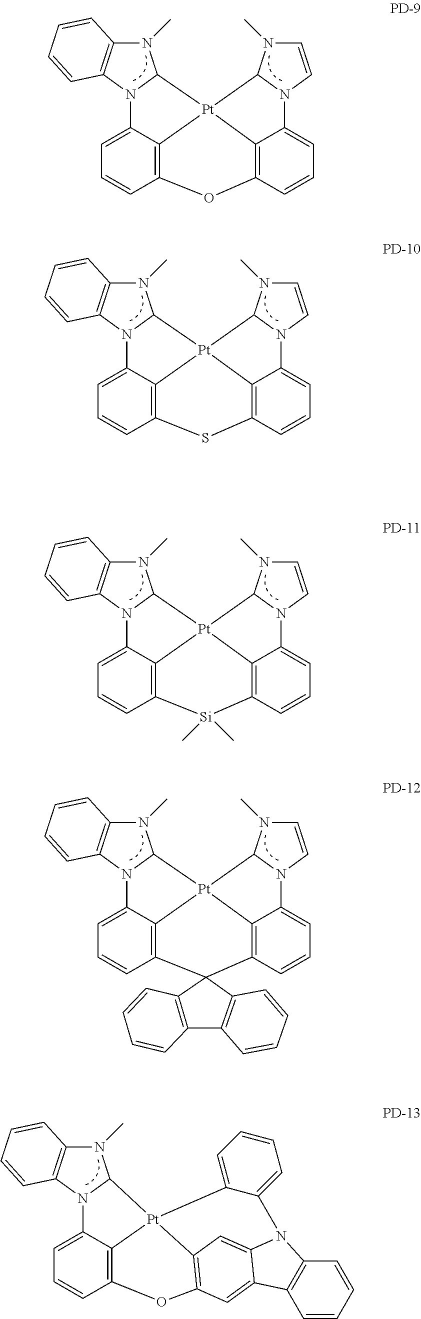

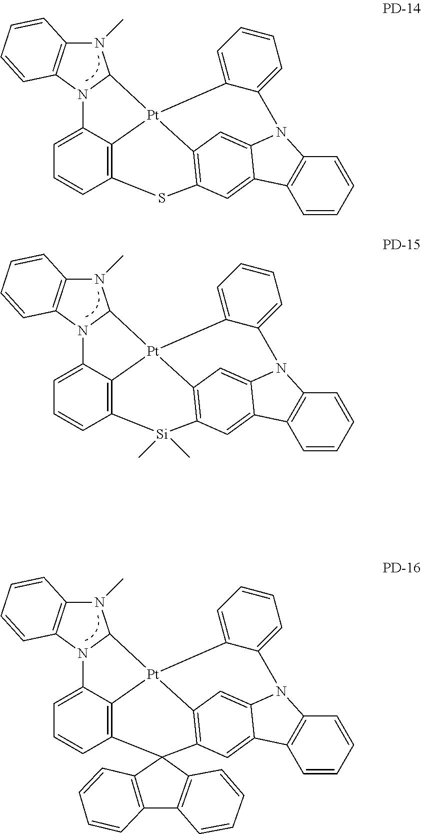

The emission layer EML may include a hole transporting host and an electron transporting host. In the emission layer EML, the hole transporting host and the electron transporting host may form an exciplex. The exciplex transfers energy to a phosphorescent sensitizer and a fluorescent dopant through Forster energy transfer, and accordingly, fluorescent light may be emitted.

The exciplex formed by the hole transporting host and the electron transporting host has a triplet state energy level which is different from the triplet state energy level of the hole transporting host and the electron transporting host, and may have a new triplet state energy level. The triplet state energy of the exciplex formed by the hole transporting host and the electron transporting host corresponds to a difference in energy level between Lowest Unoccupied Molecular Orbital (LUMO) of the electron transporting host and Highest Occupied Molecular Orbital (HOMO) of the hole transporting host.

For example, the exciplex formed by the hole transporting host and the electron transporting host in a light emitting element may have an absolute value in a range of about 2.4 eV to about 3.0 eV of the triplet state energy level. The triplet state energy level of the exciplex may have a value smaller than the energy gap of each host material. The energy gap may be a difference in energy level between LUMO and HOMO. For example, the hole transporting host and the electron transporting host may each have an energy gap equal to or greater than about 3.0 eV, and the exciplex may have a triplet state energy level equal to or less than about 3.0 eV. However, this is presented as an example, and the triplet state energy level of the exciplex is not limited thereto.

In an embodiment, the hole transporting host may include a carbazole compound represented by Formula 2. The carbazole compound represented by Formula 2 may include two carbazole groups.

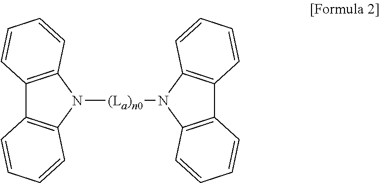

In Formula 2, n0 may be 1 or 2. In Formula 2, Lₐ may be a substituted or unsubstituted arylene group having 6 to 20 ring-forming carbon atoms. When n0 is 2, two Lₐ groups may be the same as or different from each other. For example, the two Lₐ groups may each be an unsubstituted phenylene group. As another example, one Lₐ groups may be an unsubstituted phenylene group, and the other Lₐ group may be a substituted phenylene group.

The hole transporting host may include any one selected from Compound Group 3. The emission layer EML may include any one selected from Compound Group 3 as a hole transporting host.

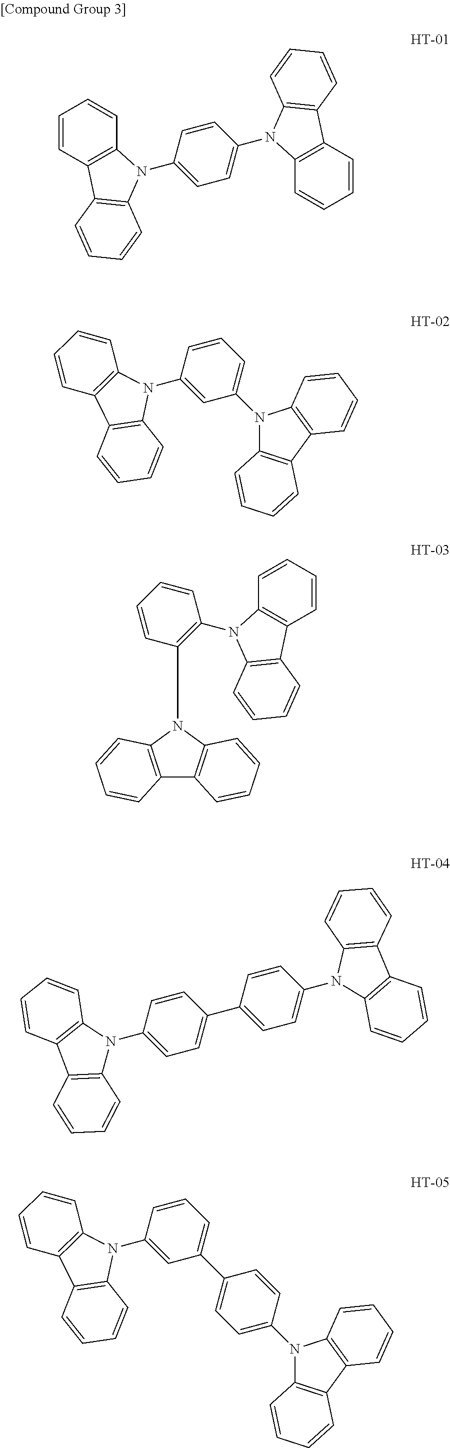

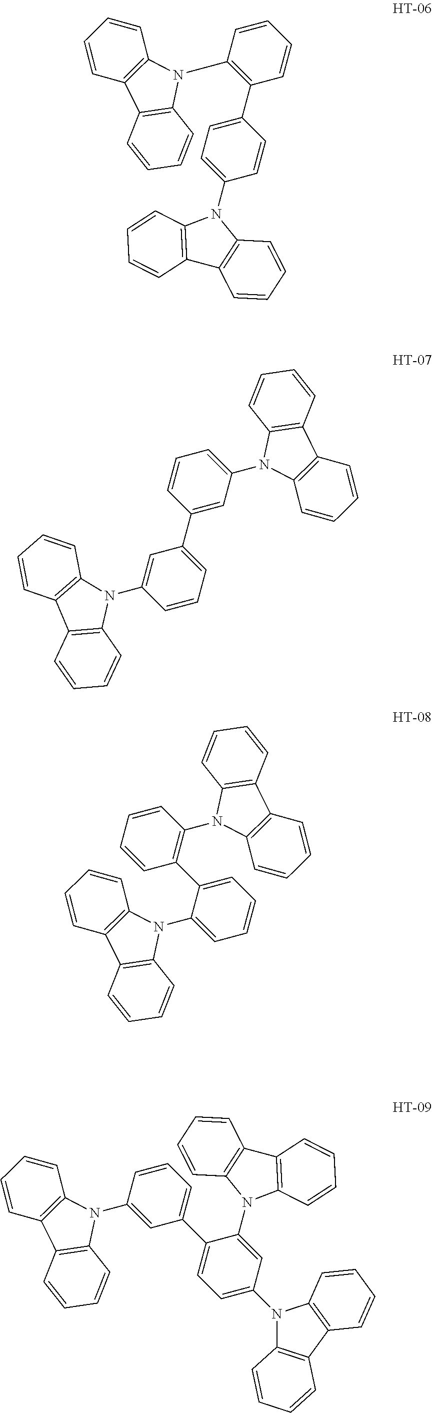 [SMILES: c1ccc(-n2c3ccccc3c3ccccc32)c(-c2ccc(-n3c4ccccc4c4ccccc43)cc2)c1 ; c1cc(-c2cccc(-n3c4ccccc4c4ccccc43)c2)cc(-n2c3ccccc3c3ccccc32)c1 ; c1ccc(-n2c3ccccc3c3ccccc32)c(-c2ccccc2-n2c3ccccc3c3ccccc32)c1 ; c1cc(-c2ccc(-n3c4ccccc4c4ccccc43)cc2-n2c3ccccc3c3ccccc32)cc(-n2c3ccccc3c3ccccc32)c1]

In an embodiment, the electron transporting host may include a triazine compound represented by Formula 3.

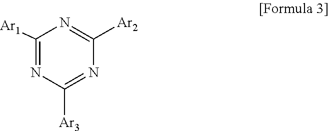

In Formula 3, Ar₁ to Ar₃ may each independently be a substituted or unsubstituted aryl group having 6 to 20 ring-forming carbon atoms, or a substituted or unsubstituted heteroaryl group having 2 to 20 ring-forming carbon atoms. For example, Ar₁ to Ar₃ may each independently be a substituted or unsubstituted phenyl group or a substituted or unsubstituted carbazole group. However, this is presented as an example, and embodiments are not limited thereto.

The electron transporting host may include any one selected from Compound Group 4. The emission layer EML may include any one selected from Compound Group 4 as an electron transporting host.

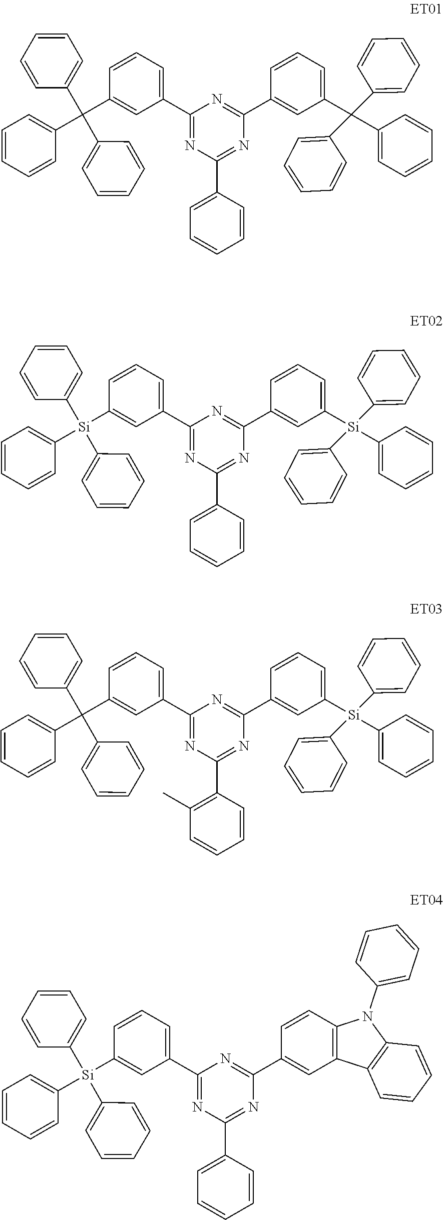 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc([Si](c3ccccc3)(c3ccccc3)c3ccccc3)c2)n1 ; c1ccc(-c2nc(-c3cccc([Si](c4ccccc4)(c4ccccc4)c4ccccc4)c3)nc(-c3ccc4c(c3)c3ccccc3n4-c3ccccc3)n2)cc1]

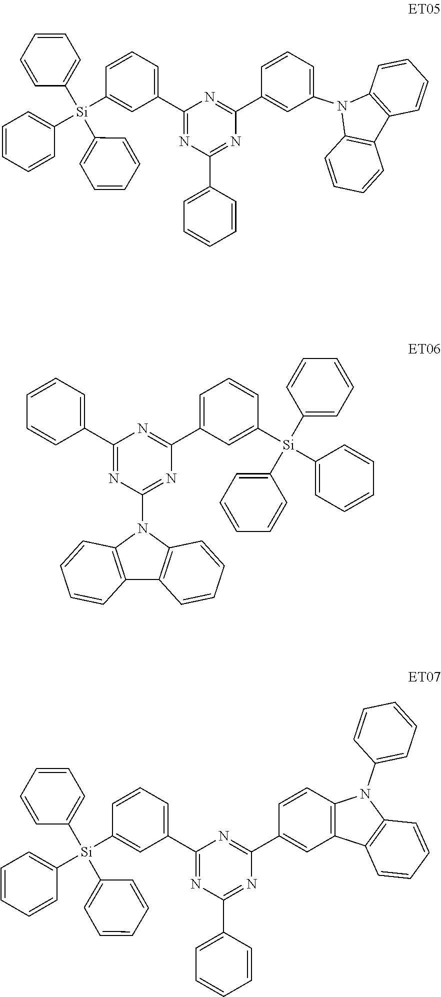 [SMILES: c1ccc(-c2nc(-c3cccc(-n4c5ccccc5c5ccccc54)c3)nc(-c3cccc([Si](c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-n3c4ccccc4c4ccccc43)n2)cc1 ; c1ccc(-c2nc(-c3cccc([Si](c4ccccc4)(c4ccccc4)c4ccccc4)c3)nc(-c3ccc4c(c3)c3ccccc3n4-c3ccccc3)n2)cc1]

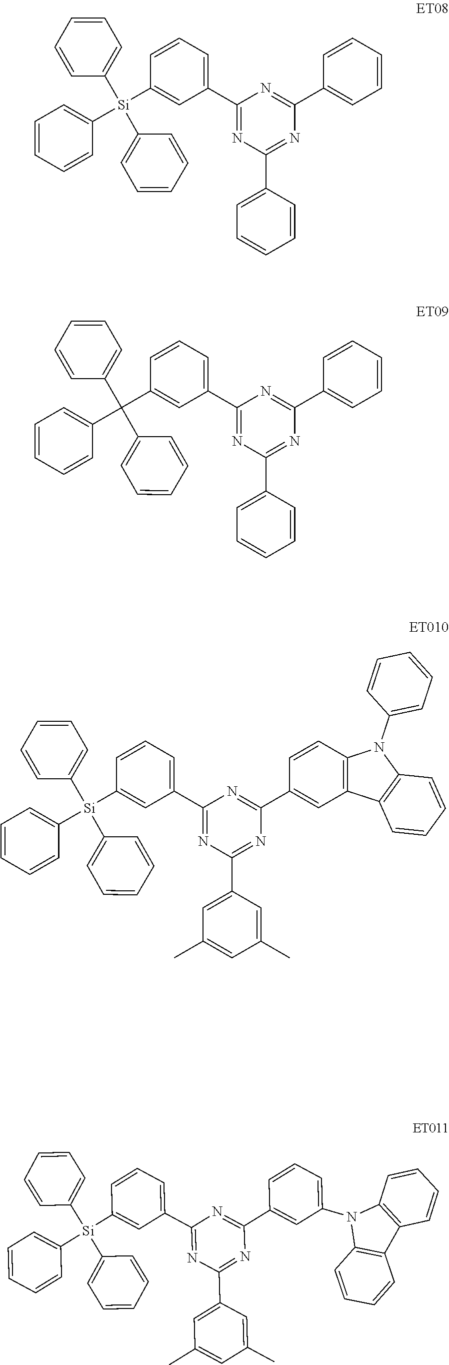 [SMILES: c1ccc(-c2nc(-c3ccccc3)nc(-c3cccc([Si](c4ccccc4)(c4ccccc4)c4ccccc4)c3)n2)cc1 ; c1ccc(-c2nc(-c3ccccc3)nc(-c3cccc(C(c4ccccc4)(c4ccccc4)c4ccccc4)c3)n2)cc1 ; Cc1cc(C)cc(-c2nc(-c3cccc([Si](c4ccccc4)(c4ccccc4)c4ccccc4)c3)nc(-c3ccc4c(c3)c3ccccc3n4-c3ccccc3)n2)c1 ; Cc1cc(C)cc(-c2nc(-c3cccc(-n4c5ccccc5c5ccccc54)c3)nc(-c3cccc([Si](c4ccccc4)(c4ccccc4)c4ccccc4)c3)n2)c1]

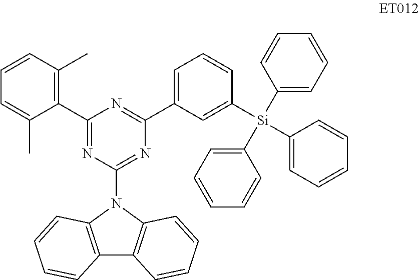 [SMILES: Cc1cccc(C)c1-c1nc(-c2cccc([Si](c3ccccc3)(c3ccccc3)c3ccccc3)c2)nc(-n2c3ccccc3c3ccccc32)n1]

The emission layer EML according to an embodiment may emit fluorescent light. In the emission layer EML, the fluorescent dopant may absorb energy to emit light, and may receive energy from a phosphorescent sensitizer. The phosphorescent sensitizer may receive energy from an exciplex. In the emission layer EML, Forster energy transfer may occur from the exciplex to the phosphorescent sensitizer. Forster energy transfer may occur from the phosphorescent sensitizer to the fluorescent dopant.

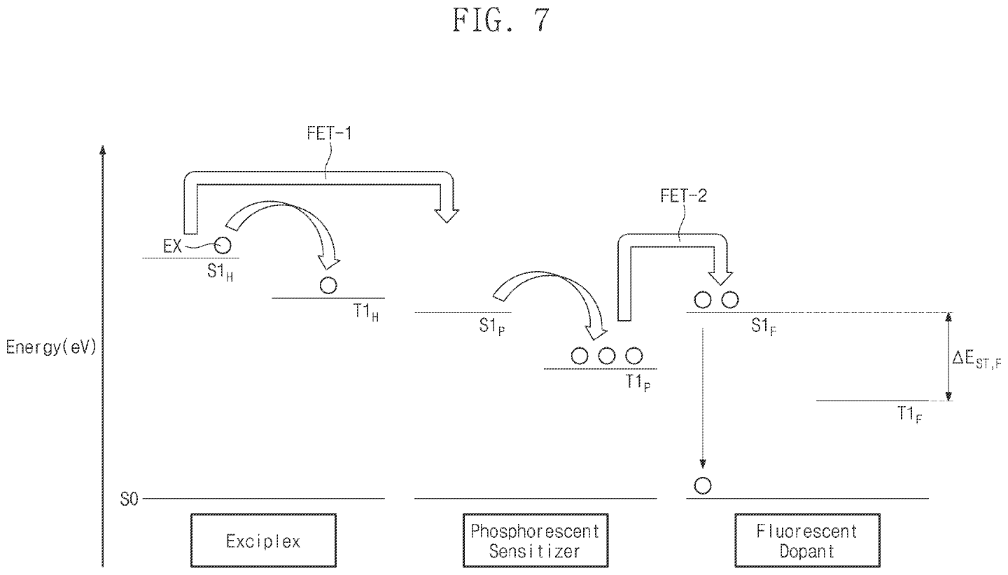

In FIG. 7, triplet state energy levels T1_{H}, T1_{P}, and T1_{F} and singlet state energy levels S1_{H}, S1_{P}, and S1_{F} of the exciplex, the phosphorescent sensitizer, and the fluorescent dopant, respectively, are shown. A ground state energy level S0 of each of the exciplex, the phosphorescent sensitizer, and the fluorescent dopant is also shown. The exciplex is formed by the hole transporting host and the electron transporting host, and may have a triplet state energy level which is different from the triplet state energy level of the hole transporting host and the electron transporting host, and may have a new triplet state energy level T1_{H}.

Referring to FIG. 7, excitons EX may be transferred to the phosphorescent sensitizer through first Forster energy transfer FET-1 from the exciplex, and the excitons EX transferred to the phosphorescent sensitizer may be transferred to the fluorescent dopant from the phosphorescent sensitizer through second Forster energy transfer FET-2. The excitons EX move from the singlet state to the ground state, and thus light may be emitted.

The triplet state energy level T1_{H} of the exciplex may be greater than the triplet state energy level T1_{P} of the phosphorescent sensitizer. The triplet state energy level T1_{P} of the phosphorescent sensitizer may be greater than the triplet state energy level T1_{F} of the fluorescent dopant. Accordingly, back energy transfer from the triplet state of the fluorescent dopant to the triplet state of the phosphorescent sensitizer or the triplet state of the exciplex may be prevented.

A difference ΔE_{ST,F} between the singlet state energy level S1_{F} of the fluorescent dopant and the triplet state energy level T1_{F} of the fluorescent dopant may be in a range of about 0.4 eV to about 1.0 eV. Accordingly, in the fluorescent dopant, excitons may not readily move from the triplet state to the singlet state. For example, reverse intersystem crossing (RISC) does not occur in the fluorescent dopant, and thus thermally activated delayed fluorescence (TADF) emission may not occur.

Dexter energy transfer may occur from the triplet state of the phosphorescent sensitizer to the triplet state of the fluorescent dopant. When such Dexter energy transfer occurs, excitons in the triplet state of the fluorescent dopant may be subjected to nonradiative decay. The excitons in the triplet state of the fluorescent dopant may not readily move from the triplet state of the fluorescent dopant to the singlet state of the fluorescent dopant, and thus the excitons in the triplet state of the fluorescent dopant are not emitted and may decay.

A dopant having a small difference between the singlet state energy level (S1) and the triplet state energy (T1) is used as a thermally activated delayed fluorescence (TADF) light emitting material. For example, a dopant having a difference equal to or less than 0.2 eV between the singlet state energy level (S1) and the triplet state energy level (T1) may be used as a thermally activated delayed fluorescence light emitting material. As the time the excitons stay in the triplet state for thermally activated delayed fluorescence from the dopant increases, roll-off is significant at high luminance, resulting in reduced lifespan of a light emitting element.

In the emission layer EML included in the light emitting element ED according to an embodiment, the singlet state energy level of the fluorescent dopant may be greater than the triplet state energy level of the fluorescent dopant by about 0.4 eV to about 1.0 eV. In the fluorescent dopant having a difference equal to or greater than about 0.4 eV between the singlet state energy level and the triplet state energy level, the triplet state energy level is greater than the singlet state energy level by an amount equal to or greater than about 0.4 eV, and thus reverse intersystem crossing (RISC) in which excitons in the triplet state move to the singlet state may be prevented. The emission layer EML including the fluorescent dopant according to an embodiment may emit fluorescent light without thermally activated delayed fluorescence. Accordingly, the time the excitons stay in the triplet state is reduced, and the light emitting element ED including the fluorescent dopant according to an embodiment may exhibit long lifespan characteristics.

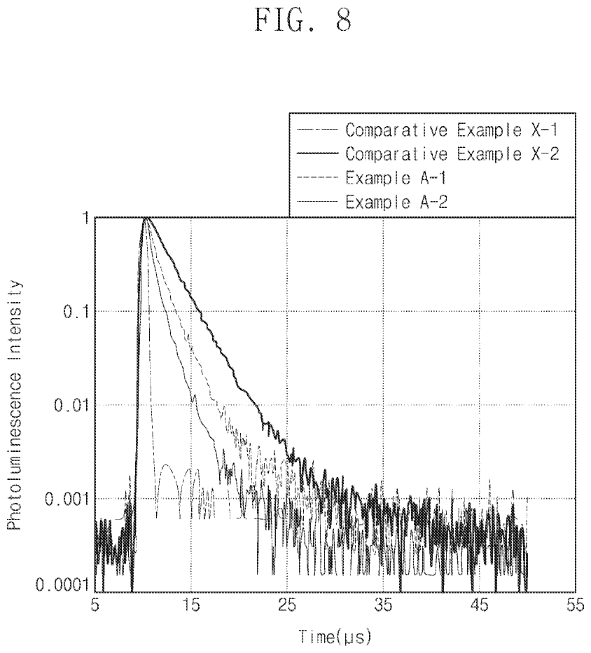

FIG. 8 is a graph showing the measurement of photoluminescence intensity over time in light emitting elements of Comparative Examples and Examples. The photoluminescence intensity shown in FIG. 8 is a normalized value. The light emitting elements of Comparative Examples and Examples were manufactured in the same manner except for a dopant in an emission layer. For example, the light emitting elements of Comparative Examples and Examples include identical hole transporting hosts and electron transporting hosts.

In FIG. 8, HT-08 according to an embodiment was used as the hole transporting host, and ET-04 according to an embodiment was used as the electron transporting host. In FIG. 8, FD-1 according to an embodiment was used as the fluorescent dopant, and PD-5 according to an embodiment was used as the phosphorescent sensitizer.

The light emitting element of Comparative Example X-1 includes a fluorescent dopant and does not include a phosphorescent sensitizer. The light emitting element of Comparative Example X-2 includes a phosphorescent sensitizer and does not include a fluorescent dopant.

The light emitting elements of Examples A-1 and A-2 are light emitting elements according to an embodiment. The light emitting element of Example A-1 includes a phosphorescent sensitizer and a fluorescent dopant, and includes a fluorescent dopant at 0.4 vol %, with respect to a total volume of the hole transporting host, the electron transporting host, the phosphorescent sensitizer, and the fluorescent dopant. The light emitting element of Example A-2 includes a phosphorescent sensitizer and a fluorescent dopant, and includes a fluorescent dopant at 0.8 vol %, with respect to a total volume of the hole transporting host, the electron transporting host, the phosphorescent sensitizer, and the fluorescent dopant. The light emitting elements of Examples A-1 and A-2 include a phosphorescent sensitizer at 13 vol %, with respect to a total volume of the hole transporting host, the electron transporting host, the phosphorescent sensitizer, and the fluorescent dopant.

Referring to FIG. 8, it is seen that the time taken for photoluminescence intensity to decrease from 1 to 0.1 was longer in the light emitting elements according to Comparative Example X-2, and Examples A-1 and A-2 than in the light emitting element according to Comparative Example X-1. It is seen that compared to the light emitting element of Comparative Example X-1, the light emitting elements of Comparative Example X-2, Examples A-1 and A-2 exhibit increased service life. The light emitting element of an embodiment includes a fluorescent dopant according to an embodiment, and includes a fluorescent dopant having a difference equal to or greater than about 0.4 eV between the singlet state energy level and the triplet state energy level. Accordingly, it is confirmed that the light emitting element of an embodiment including the fluorescent dopant having a difference equal to or greater than about 0.4 eV between the singlet state energy level and the triplet state energy level exhibits long service life.

Table 1 shows differences in central emission wavelength, full width at half maximum, and maximum wavelength value of the fluorescent dopant according to an embodiment. The central emission wavelength λmax indicates central emission wavelength having the maximum emission intensity at an emission peak. The full width at half maximum (FWHM) indicates full width at half maximum in emission spectrum. The difference Δλ in the maximum wavelength value indicates a difference in the wavelength value according to Stokes shift. The difference Δλ in the maximum wavelength value indicates a difference between the maximum wavelength when energy is absorbed and the maximum wavelength when energy is emitted. As the fluorescent dopant, FD-1 according to an embodiment was used.

TABLE 1

| λₘₐₓ | Δλ | FWHM |
|---|---|---|
| 458 nm | 12 nm | 18 nm |

Referring to Table 1, it is seen that, in the fluorescent dopant according to an embodiment, the difference Δλ in the maximum wavelength value is 12 nm and the full width at half maximum (FWHM) is equal to or less than about 20 nm. FD-1, which is the fluorescent dopant according to an embodiment, is an MR type fluorescent dopant and includes a pyrenyl group. Accordingly, it is seen that the light emitting element ED according to an embodiment including the MR type fluorescent dopant has a full width at half maximum (FWHM) equal to or less than about 20 nm and thus exhibits excellent color purity.

Table 4 shows evaluation results of the light emitting elements of Comparative Examples and Examples. The central emission wavelength λₘₐₓ indicates central emission wavelength having the maximum emission intensity at an emission peak. Element lifetime T₉₅ indicates the time taken for the brightness of a light emitting element to decrease to 95% at a luminance of 1000 nits.

Table 2 shows a hole transporting host, an electron transporting host, a phosphorescent sensitizer, and a fluorescent dopant used when manufacturing the light emitting elements of Comparative Examples and Examples. Table 3 shows the energy levels of the fluorescent dopants used in the manufacture of the light emitting elements according to Comparative Examples and Examples.

TABLE 2

| Example | Hole | Electron | Phos- | Fluor- |
|---|---|---|---|---|
| of element | transporting | transporting | phorescent | escent |
| manufacturing | host | host | sensitizer | dopant |
| Example B-1 | HT-08 | ET04 | PD-5 | FD-1 |
| Example B-2 | | | | FD-2 |
| Comparative | | | | TA-1 |
| Example Y-1 | | | | |
| Comparative | | | | TA-2 |
| Example Y-2 | | | | |

Referring to Table 2, in the light emitting elements of Comparative Examples and Examples, the same material was used as a hole transporting host, an electron transporting host, and a phosphorescent sensitizer. In the light emitting element of Comparative Example Y-1, TA-1 was used as a fluorescent dopant, and in the light emitting element of Comparative Example Y-2, TA-2 was used as a fluorescent dopant. In the light emitting element of Example B-1, FD-1 was used as a fluorescent dopant, and in the light emitting element of Example B-2, FD-2 was used as a fluorescent dopant.

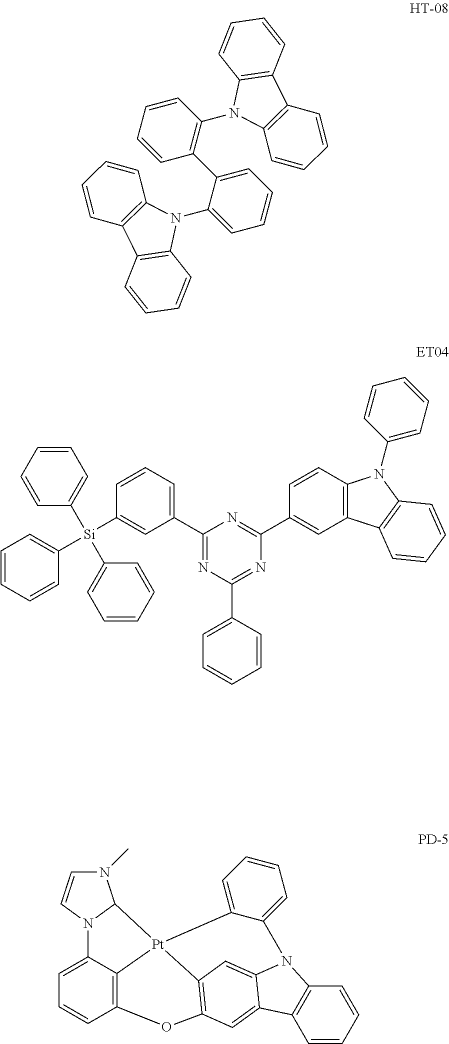

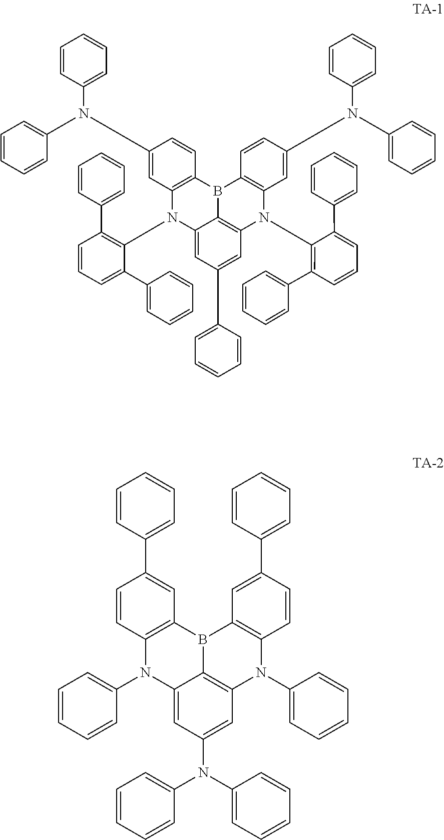 [SMILES: c1ccc(-c2cc3c4c(c2)N(c2c(-c5ccccc5)cccc2-c2ccccc2)c2cc(N(c5ccccc5)c5ccccc5)ccc2B4c2ccc(N(c4ccccc4)c4ccccc4)cc2N3c2c(-c3ccccc3)cccc2-c2ccccc2)cc1 ; c1ccc(-c2ccc3c(c2)B2c4cc(-c5ccccc5)ccc4N(c4ccccc4)c4cc(N(c5ccccc5)c5ccccc5)cc(c42)N3c2ccccc2)cc1]

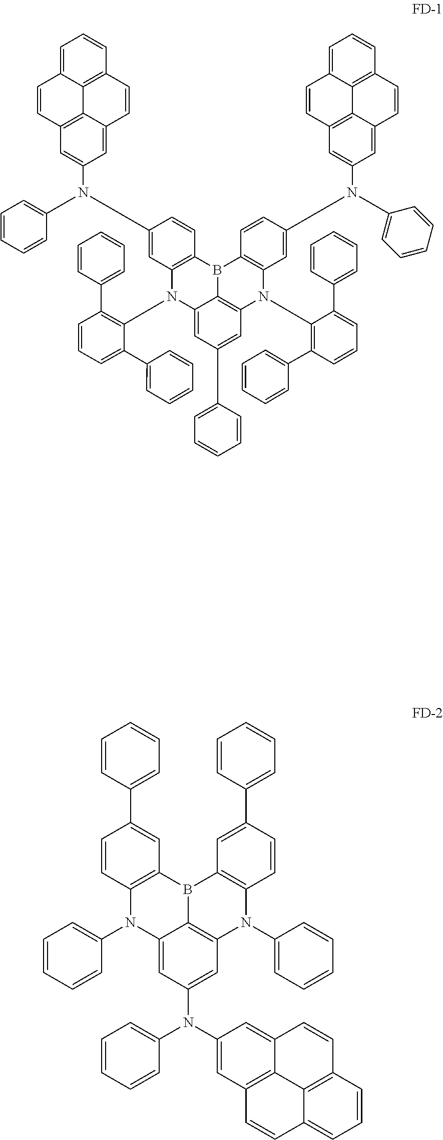 [SMILES: c1ccc(-c2cc3c4c(c2)N(c2c(-c5ccccc5)cccc2-c2ccccc2)c2cc(N(c5ccccc5)c5cc6ccc7cccc8ccc(c5)c6c78)ccc2B4c2ccc(N(c4ccccc4)c4cc5ccc6cccc7ccc(c4)c5c67)cc2N3c2c(-c3ccccc3)cccc2-c2ccccc2)cc1 ; c1ccc(-c2ccc3c(c2)B2c4cc(-c5ccccc5)ccc4N(c4ccccc4)c4cc(N(c5ccccc5)c5cc6ccc7cccc8ccc(c5)c6c78)cc(c42)N3c2ccccc2)cc1]

In Table 3, S1 indicates a singlet state energy level, and T1 indicates a triplet state energy level. ΔE_{ST} indicates a difference in energy level between a singlet state and a triplet state.

TABLE 3

| Item | S1 (eV) | T1 (eV) | ΔE_{ST} |
|---|---|---|---|
| FD-1 | 2.81 | 2.05 | 0.76 |
| FD-2 | 2.80 | 2.05 | 0.75 |
| TA-1 | 2.81 | 2.63 | 0.18 |
| TA-2 | 2.80 | 2.64 | 0.16 |

TABLE 4

| Example of manu- | Driving | | T₉₅ (hr, |
|---|---|---|---|
| facturing device | voltage (V) | λₘₐₓ | 1000 nit) |
| Example B-1 | 5.3 | 462 | 65.8 |
| Example B-2 | 5.5 | 461 | 72.8 |
| Comparative | 5.3 | 461 | 58.2 |
| Example Y-1 | | | |
| Comparative | 5.4 | 462 | 60.8 |
| Example Y-2 | | | |

Referring to Table 4, it is seen that the light emitting elements of Comparative Examples Y-1 and Y-2 have a service life of less than 61 hours while the light emitting elements of Examples B-1 and B-2 have a service life of 65 hours or greater. It is seen that the light emitting elements of Examples B-1 and B-2 have greater service life than the light emitting elements of Comparative Examples Y-1 and Y-2. It is seen that the light emitting elements of Examples and Comparative Examples have a similar level of driving voltage, and emit blue light in a wavelength range of about 460 nm to about 462 nm.

The light emitting elements of Comparative Examples Y-1 and Y-2 each include TA-1 and TA-2 as a fluorescent dopant, respectively. Referring to Table 3, a difference in energy level between a singlet state and a triplet state of the fluorescent dopants of TA-1 and TA-2 is equal to or less than about 0.2 eV, and it is believed to be used as a material for thermally activated delayed fluorescence. Accordingly, it is believed that the light emitting elements of Comparative Examples Y-1 and Y-2 have a shorter service life than the light emitting elements according to the Examples.

The light emitting elements of Examples B-1 and B-2 are light emitting elements according to an embodiment, and include FD-1 and FD-2 as a fluorescent dopant, respectively. Referring to Table 3, FD-1 and FD-2 are fluorescent dopants having a difference in a range of about 0.4 eV to about 1.0 eV between a singlet state energy level and a triplet state level. It is seen that FD-1 and FD-2 have a lower triplet state energy level than TA-1 and TA-2. Accordingly, the light emitting element of an embodiment including the fluorescent dopant having a difference in a range of about 0.4 eV to about 1.0 eV between the singlet state energy level and the triplet state energy level may exhibit long service life characteristics.

Table 5 shows color coordinates (x, y) measured in the light emitting elements of Comparative Examples and Examples. In the light emitting elements of Comparative Examples and Examples, the same material was used for the hole transporting host and the electron transporting host.

The light emitting element of Comparative Example Z-1 includes TA-1 and PD-5, and the light emitting element of Comparative Example Z-2 includes TA-1. The light emitting element of Example C-1 includes FD-1 and PD-5 according to embodiments, and Example C-2 includes FD-1 according to an embodiment. The light emitting element of Comparative Example Z-1 and the light emitting element of Example C-1 includes the same phosphorescent agent, and the light emitting element of Comparative Example Z-2 and the light emitting element of Example C-2 do not include a phosphorescent sensitizer.

TABLE 5

| Example of element | Color coordinates | Color |
|---|---|---|
| manufacturing | (x, y) | coordinates (z) |
| Comparative Example Z-1 | 0.135, 0.186 | 0.679 |
| Example C-1 | 0.139, 0.166 | 0.695 |
| Comparative Example Z-2 | 0.140, 0.139 | 0.721 |
| Example C-2 | 0.144, 0.123 | 0.733 |

Referring to Table 5, it is seen that light emitting elements according to Comparative Examples and Examples emit blue light. It is seen that the light emitting element of Example C-1 has higher color purity of blue light than the light emitting element of Comparative Example Z-1. The light emitting element of Comparative Example Z-1 and the light emitting element of Example C-1 have different types of fluorescent dopants, and it is believed that the light emitting element of Example C-1 includes FD-1 according to an embodiment as a fluorescent dopant to have high color purity.

The light emitting element of Example C-2 has higher color purity of blue light than the light emitting element of Comparative Example Z-2. The light emitting element of Comparative Example Z-2 and the light emitting element of Example C-2 have different types of fluorescent dopants, and it is believed that the light emitting element of Example C-2 includes FD-1 according to an embodiment as a fluorescent dopant to have high color purity. Referring to Table 1, FD-1 according to an embodiment is a fluorescent dopant having a full width at half maximum equal to or less than about 20 nm. Accordingly, the light emitting element according to an embodiment including the fluorescent dopant having a full width at half maximum equal to or less than about 20 nm may exhibit excellent color purity.

Referring back to FIGS. 3 to 6, the first electrode EL1 has conductivity. The first electrode EL1 may be formed of a metal material, a metal alloy, or a conductive compound. The first electrode EL1 may be an anode or a cathode. However, embodiments are not limited thereto. For example, the first electrode EL1 may be a pixel electrode. The first electrode EL1 may be a transmissive electrode, a transflective electrode, or a reflective electrode. When the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca, LiF/Al, Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the first electrode EL1 may have a three-layer structure of ITO/Ag/ITO. However, embodiments are not limited thereto, and the first electrode EL1 may include the above-described metal materials, a combination of two or more metal materials selected from the above-described metal materials, or oxides of the above-described metal materials. The first electrode EL1 may have a thickness in a range of about 700 Å to about 10,000 Å. For example, the first electrode EL1 may have a thickness in a range of about 1,000 Å to about 3,000 Å.

The hole transport region HTR is provided on the first electrode EL1. The hole transport region HTR may include at least one of a hole injection layer HIL, a hole transport layer HTL, a buffer layer (not shown), a light emitting auxiliary layer (not shown), or an electron blocking layer EBL. The hole transport region HTR may have, for example, a thickness in a range of about 50 Å to about 15,000 Å.

The hole transport region HTR may be a layer formed of a single material, a layer formed of different materials, or a multilayer structure having layers formed of different materials.

For example, the hole transport region HTR may have a single-layer structure formed of a hole injection layer HIL or a hole transport layer HTL, or a single-layer structure formed of a hole injection material or a hole transport material. For example, the hole transport region HTR may have a single-layer structure formed of different materials, or a structure in which a hole injection layer HIL/hole transport layer HTL, a hole injection layer HIL/hole transport layer HTL/buffer layer (not shown), a hole injection layer HIL/buffer layer (not shown), a hole transport layer HTL/buffer layer (not shown), or a hole injection layer HIL/hole transport layer HTL/electron blocking layer EBL are stacked in its respective stated order from the first electrode EL1, but embodiments are not limited thereto.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

The hole transport region HTR may include a compound represented by Formula H-1.

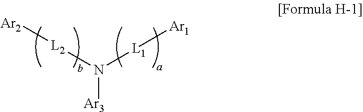

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a orb is 2 or greater, multiple L₁ groups and multiple L₂ groups may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In Formula H-1, Ar₃ may be a substituted or unsubstituted aryl group having 6 to 30 ring-forming carbon atoms.

In an embodiment, a compound represented by Formula H-1 may be a monoamine compound. In another embodiment, the compound represented by Formula H-1 may be a diamine compound in which at least one of Ar₁ to Ar₃ includes an amine group as a substituent. In still another embodiment, the compound represented by Formula H-1 may be a carbazole-based compound including a substituted or unsubstituted carbazole group in at least one of Ar₁ or Ar₂ or a substituted or unsubstituted fluorene-based group in at least one of Ar₁ or Ar₂.

The compound represented by Formula H-1 may be any one selected from Compound Group H. However, the compounds listed in Compound Group H are only presented as examples, and the compound represented by Formula H-1 is not limited to Compound Group H.

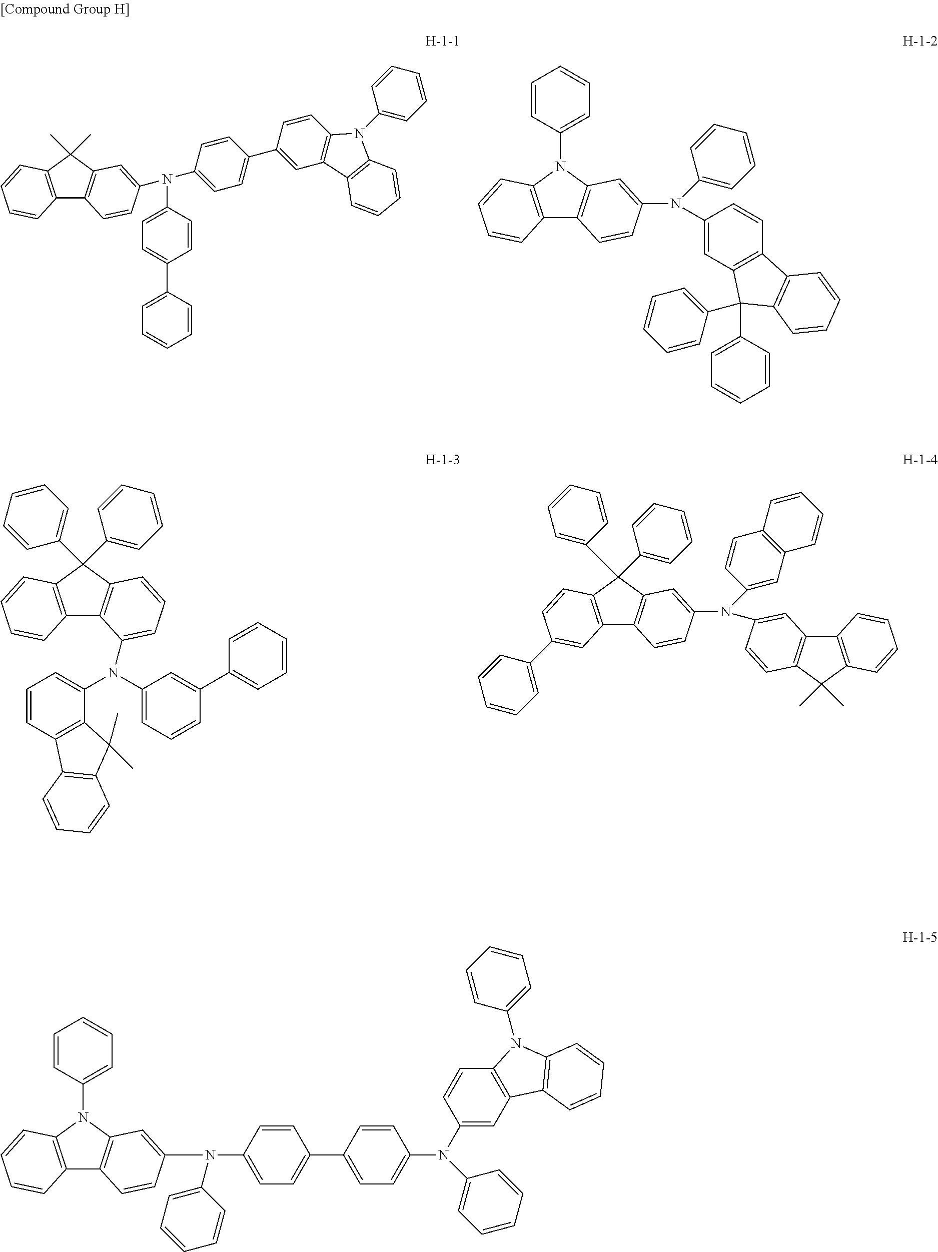 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21 ; c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1]

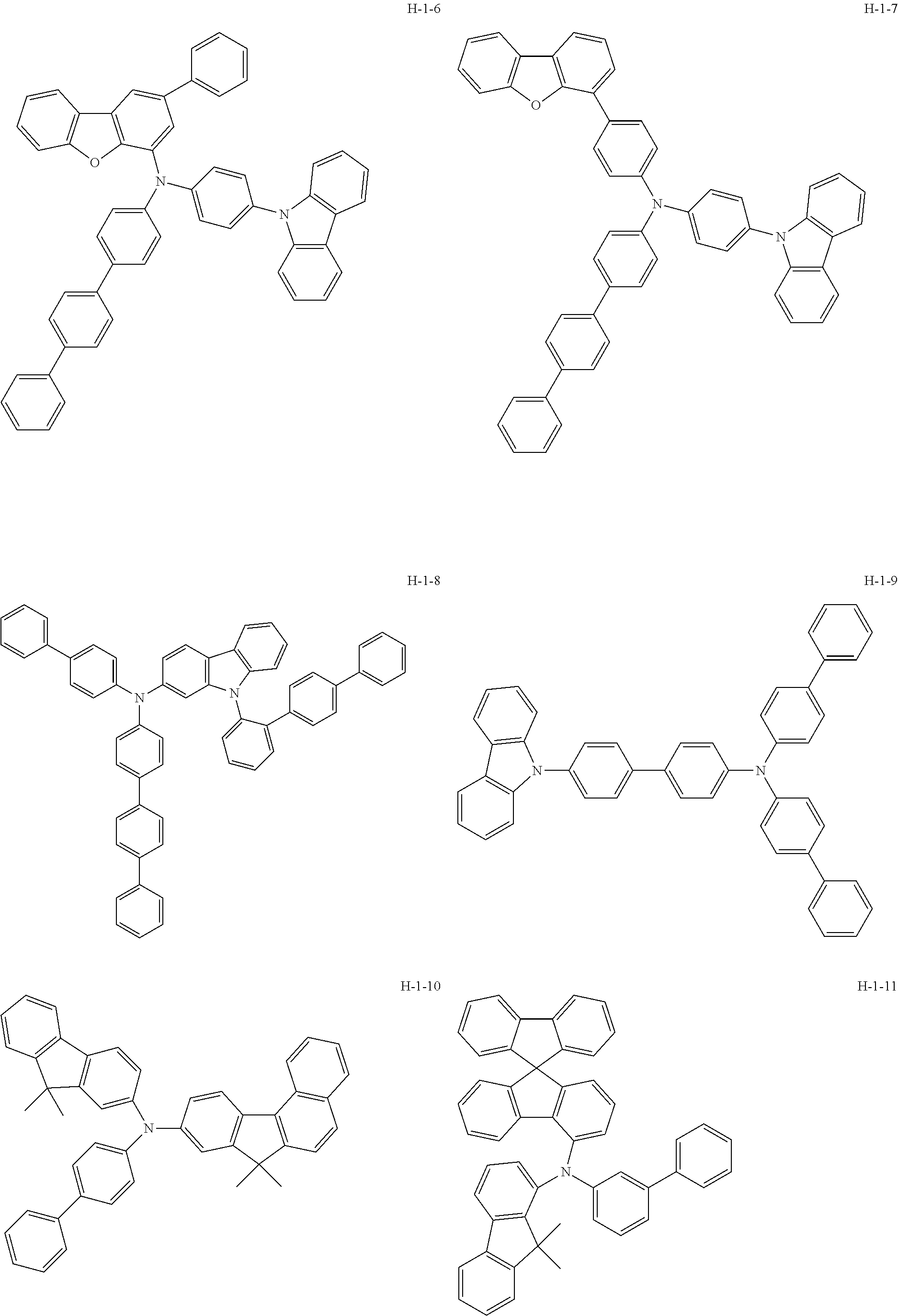

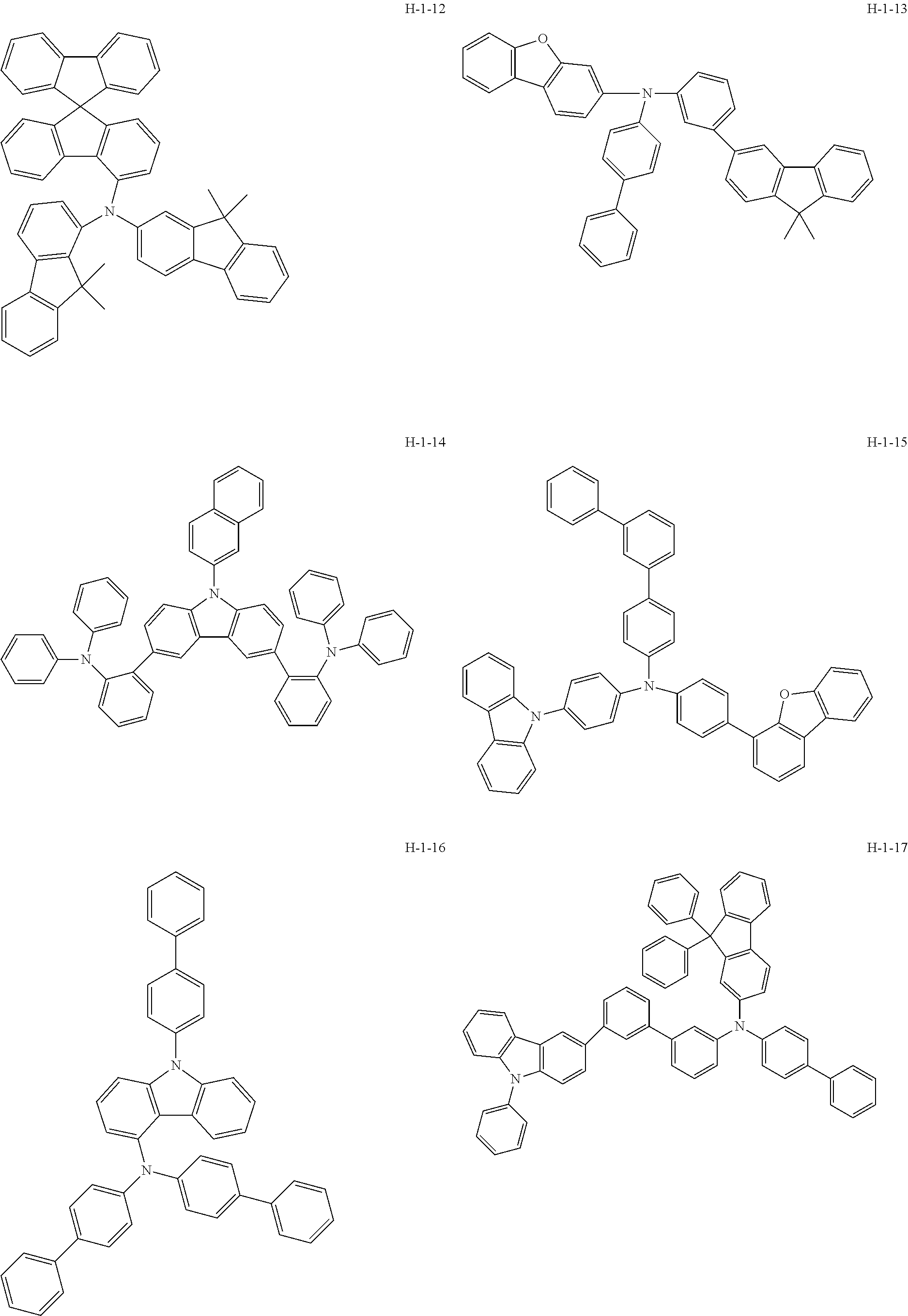

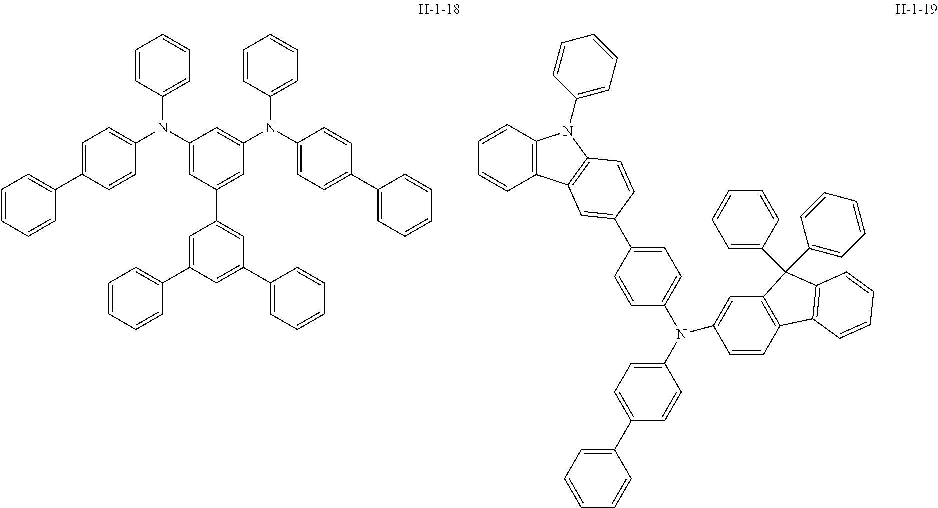 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N¹,N¹′-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f:2′,3′-h] quinoxaline-2,3,6,7,10,11-hexacarbonitrile (HAT-CN), etc.

The hole transport region HTR may include carbazole-based derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphthalene-1-yl)-N,N′-diphenyl-benzidine (NPB), 4,4′-cyclohexylidene bis[N,N-bis(4-methylphenyl)benzeneamine] (TAPC), 4,4′-bis[N,N′-(3-tolyl)amino]-3,3′-dimethylbiphenyl (HMTPD), 9-(4-tert-butylphenyl)-3,6-bis(triphenylsilyl)-9H-carbazole (CzSi), 9-phenyl-9H-3,9′-bicarbazole (CCP), 1,3-bis(N-carbazolyl)benzene (mCP), 1,3-bis(1,8-dimethyl-9H-carbazol-9-yl)benzene (mDCP) etc.

The hole transport region HTR may include the compounds of the hole transport region described above in at least one of a hole injection layer HIL, a hole transport layer HTL, or an electron blocking layer EBL.

The hole transport region HTR may have a thickness in a range of about 100 Å to about 10,000 Å. For example, the hole transport region HTR may have a thickness in a range about 100 Å to about 5,000 Å. When the hole transport region HTR includes a hole injection layer HIL, the hole injection layer HIL may have a thickness in a range of about 30 Å to about 1,000 Å. When the hole transport region HTR includes a hole transport layer HTL, the hole transport layer HTL may have a thickness in a range of about 30 Å to about 1,000 Å. When the hole transport region HTR includes an electron blocking layer EBL, the electron blocking layer EBL may have a thickness in a range of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include at least one of halogenated metal compounds, quinone derivatives, metal oxides, or cyano group-containing compounds, but is not limited thereto. For example, the p-dopant may include halogenated metal compounds such as CuI and RbI, quinone derivatives such as tetracyanoquinodimethane (TCNQ) and 2,3,5,6-tetrafluoro-7,7,8,8-tetracyanoquinodimethane (F4-TCNQ), metal oxides such as tungsten oxides and molybdenum oxides, cyano group-containing compounds such as dipyrazino[2,3-f: 2′,3′-h] quinoxaline-2,3,6,7,10,11-hexacarbonitrile (HAT-CN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but is not limited thereto.

As described above, the hole transport region HTR may further include at least one of a buffer layer (not shown) or an electron blocking layer EBL in addition to the hole injection layer HIL and the hole transport layer HTL. The buffer layer (not shown) may compensate for a resonance distance according to a wavelength of light emitted from an emission layer EML, and may thus increase luminous efficiency. Materials which may be included in the hole transport region HTR may be used as materials included in the buffer layer (not shown). The electron blocking layer EBL may prevent electrons from being injected from the electron transport region ETR to the hole transport region HTR.

In the light emitting element ED of an embodiment illustrated in FIGS. 3 to 6, an electron transport region ETR is provided on the emission layer EML. The electron transport region ETR may include at least one of a hole blocking layer HBL, an electron transport layer ETL, or an electron injection layer EIL, but embodiments are not limited thereto.

The electron transport region ETR may be a layer formed of a single material, a layer formed of different materials, or a multilayer structure having layers formed of different materials.

For example, the electron transport region ETR may have a single layer structure of an electron injection layer EIL or an electron transport layer ETL, or may have a single layer structure formed of an electron injection material or an electron transport material. The electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but is not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, a laser induced thermal imaging (LITI) method, etc.

The electron transport region ETR may include a compound represented by Formula ET-1.

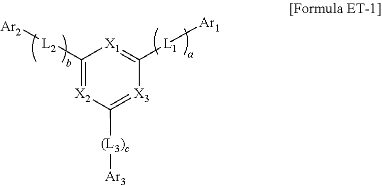

In Formula ET-1, at least one of X₁ to X₃ may be N and the remainder of X₁ to X₃ may be C(Rₐ). Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-1, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer from 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are 2 or greater, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), or a mixture thereof.

The electron transport region ETR may include halogenated metals such as LiF, NaCl, CsF, RbCl, RbI, Cul, or KI, lanthanide metals such as Yb, or co-deposition materials of a halogenated metal and a lanthanide metal. For example, the electron transport region ETR may include KI:Yb, RbI:Yb, LiF:Yb, etc. as a co-deposition material. The electron transport region ETR may include a metal oxide such as Li₂O and BaO, or 8-hydroxyl-lithium quinolate (Liq), etc., but embodiments are not limited thereto. The electron transport region ETR may also be formed of a mixture material of an electron transport material and an insulating organo-metal salt. The organo-metal salt may be a material having an energy band gap equal to or greater than about 4 eV. For example, the organo-metal salt may include metal acetates, metal benzoates, metal acetoacetates, metal acetylacetonates, or metal stearates.

The electron transport region ETR may further include, for example, at least one of 2,9-dimethyl-4,7-diphenyl-1,10-phenanthroline (BCP), diphenyl(4-(triphenyl silyl)phenyl)phosphine oxide (TSPO1), and 4,7-diphenyl-1,10-phenanthroline (Bphen) in addition to the materials described above, but embodiments are not limited thereto.

The electron transport region ETR may include the compounds of the electron transport region described above in at least one of an electron injection layer EIL, an electron transport layer ETL, or a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. When the thickness of the electron transport layer ETL satisfies the above-described range, satisfactory electron transport properties may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. When the thickness of the electron injection layer EIL satisfies the above-described ranges, satisfactory electron injection properties may be obtained without a substantial increase in driving voltage.

The second electrode EL2 is provided on the electron transport region ETR. The second electrode EL2 may be a common electrode. The second electrode EL2 may be a cathode or an anode but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In another embodiment, the second electrode EL2 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, the second electrode EL2 may include the above-described metal materials, a combination of two or more metal materials selected from the above-described metal materials, or oxides of the above-described metal materials.

Although not shown in the drawings, the second electrode EL2 may be electrically connected to an auxiliary electrode. When the second electrode EL2 is electrically connected to the auxiliary electrode, the resistance of the second electrode EL2 may decrease.

In an embodiment, the light emitting element ED may further include a capping layer CPL disposed on the second electrode EL2. The capping layer CPL may be a multilayer or a single layer.

In an embodiment, the capping layer CPL may include an organic layer or an inorganic layer. For example, when the capping layer CPL includes an inorganic material, the inorganic material may include an alkali metal compound such as LiF, an alkaline earth metal compound such as MgF₂, SiON, SiN_{X}, SiOy, etc.

For example, when the capping layer CPL includes an organic material, the organic material may include α-NPD, NPB, TPD, m-MTDATA, Alq₃ CuPc, N4,N4,N4′,N4′-tetra(biphenyl-4-yl) biphenyl-4,4′-diamine (TPD15), 4,4′,4″-tris(carbazol-9-yl)triphenylamine (TCTA), etc., or may include epoxy resins or acrylates such as methacrylates. However, embodiments are not limited thereto. For example, the capping layer CPL may include at least one of Compounds P1 to P5.

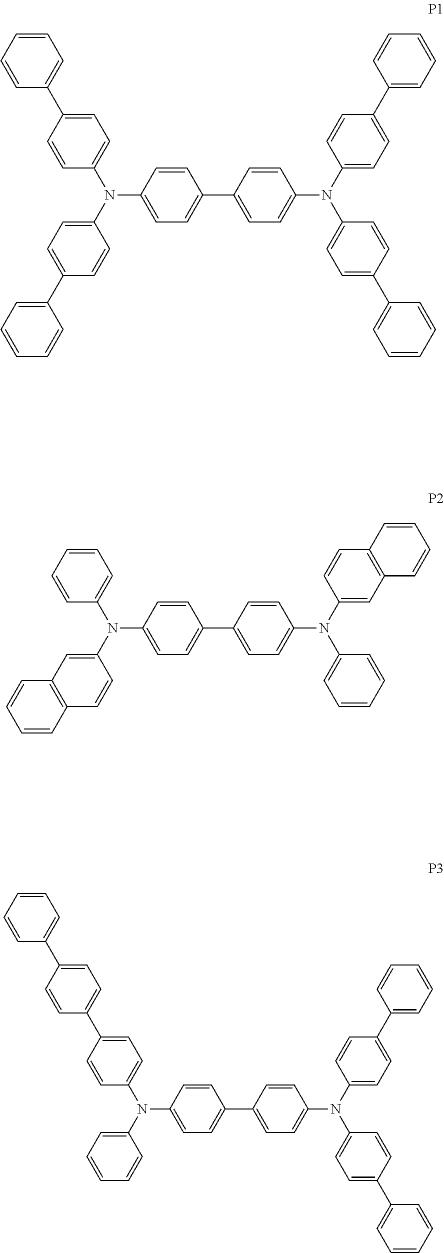 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

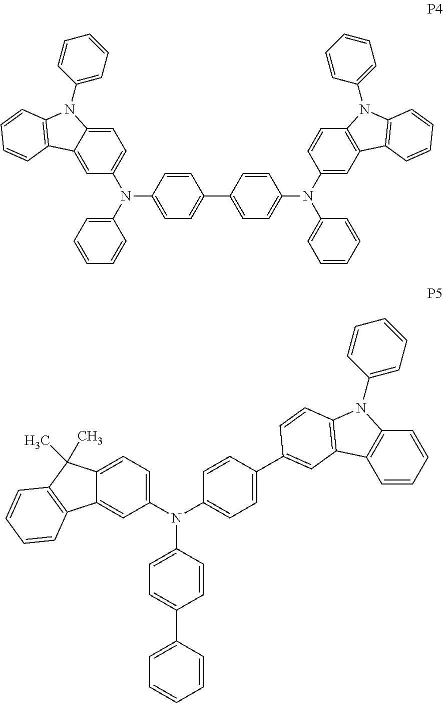 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

The capping layer CPL may have a refractive index equal to or greater than about 1.6. For example, the capping layer CPL may have a refractive index equal to or greater than about 1.6 with respect to light in a wavelength range of about 550 nm to about 660 nm.

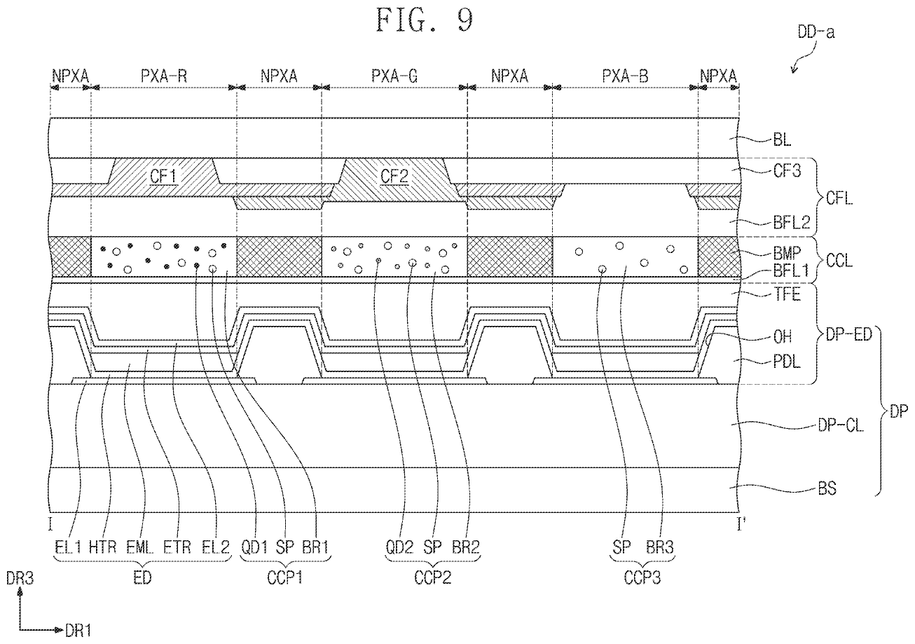

FIGS. 9 to 12 are each a schematic cross-sectional view of a display device according to an embodiment. Hereinafter, in the description of the display device according to an embodiment according to FIGS. 9 to 12, the features which overlap with the explanation of FIGS. 1 to 6 will not be described again, and the differences will be described.

Referring to FIG. 9, a display device DD-a according to an embodiment may include a display panel DP having a display element layer DP-ED, a light control layer CCL disposed on the display panel DP, and a color filter layer CFL.

In an embodiment illustrated in FIG. 9, the display panel DP may include a base layer BS, a circuit layer DP-CL provided on the base layer BS, and a display element layer DP-ED, and the display element layer DP-ED may include a light emitting element ED.

The light emitting element ED may include a first electrode ELL a hole transport region HTR disposed on the first electrode ELL an emission layer EML disposed on the hole transport region HTR, an electron transport region ETR disposed on the emission layer EML, and a second electrode EL2 disposed on the electron transport region ETR. A structure of the light emitting element ED shown in FIG. 9 may be the same as a structure of a light emitting element according to FIGS. 3 to 6 described above.

Referring to FIG. 9, in the display device DD-a, the emission layer EML may be disposed in the openings OH defined in the pixel defining films PDL. For example, the emission layer EML which is separated by the pixel defining films PDL and provided corresponding to each of light emitting regions PXA-R, PXA-G, and PXA-B may emit light in a same wavelength range. In the display device DD-a of an embodiment, the emission layer EML may emit blue light.

The light control layer CCL may be disposed on the display panel DP. The light control layer CCL may include a photoconverter. The photoconverter may be a quantum dot or a phosphor. The photoconverter may convert the wavelength of a provided light and emit the resulting light. For example, the light control layer CCL may be a layer containing quantum dots or phosphors.

The light control layer CCL may include light control units CCP1, CCP2, and CCP3. The light control units CCP1, CCP2, and CCP3 may be spaced apart from each other.

Referring to FIG. 9, a division pattern BMP may be disposed between the light control units CCP1, CCP2, and CCP3 which are spaced apart from each other, but embodiments are not limited thereto. In FIG. 9, the division pattern BMP is shown so that it does not overlap the light control units CCP1, CCP2, and CCP3, but edges of the light control units CCP1, CCP2, and CCP3 may overlap at least a portion of the division pattern BMP.

The light control layer CCL may include a first light control unit CCP1 including a first quantum dot QD1 for converting first color light provided from the light emitting element ED into second color light, a second light control unit CCP2 including a second quantum dot QD2 for converting the first color light provided from the light emitting element ED into third color light, and a third light control unit CCP3 transmitting the first color light provided from the light emitting element ED.

In an embodiment, the first light control unit CCP1 may provide red light, which is the second color light, and the second light control unit CCP2 may provide green light, which is the third color light. The third light control unit CCP3 may transmit and provide blue light, which is the first color light provided from the light emitting element ED. For example, the first quantum dot QD1 may be a red quantum dot and the second quantum dot QD2 may be a green quantum dot.

The quantum dot may be selected from a Group II-VI compound, a Group III-VI compound, a Group compound, a Group III-V compound, a Group III-II-V compound, a Group IV-VI compound, a Group IV element, a Group IV compound, or a combination thereof.

When a quantum dot includes a binary compound, a ternary compound, or a quaternary compound, the binary compound, the ternary compound, or the quaternary compound may be present in particles at a uniform concentration distribution, or may be present at a partially different concentration distribution. In an embodiment, the quantum dot may have a core/shell structure in which a quantum dot surrounds another quantum dot. A quantum dot having a core/shell structure may have a concentration gradient in which the concentration of an element that is present in the shell decreases towards the core.

A quantum dot may have a core/shell structure including a core containing nano-crystals, and a shell surrounding the core. The shell of the quantum dot may serve as a protection layer that prevents chemical deformation of the core so as to maintain semiconductor properties, and/or may serve as a charging layer that imparts electrophoretic properties to the quantum dot. The shell may be a single layer or multiple layers. Examples of the shell of the quantum dot may include a metal oxide, a non-metal oxide, a semiconductor compound, or a combination thereof.

For example, the metal oxide or the non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO, or a ternary compound such as MgAl₂O₄, CoFe₂O₄, NiFe₂O₄, and CoMn₂O₄, but embodiments are not limited thereto.

The semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

A quantum dot may have a full width of half maximum (FWHM) of a light emission wavelength spectrum equal to or less than about 45 nm. For example, the quantum dot may have a FWHM of a light emission wavelength spectrum equal to or less than about 40 nm. For example, the quantum dot may have a FWHM of a light emission wavelength spectrum equal to or less than about 30 nm. Color purity or color reproducibility may be enhanced in the above ranges. Light emitted through such a quantum dot may be emitted in all directions, so that a wide viewing angle may be improved.

The form of a quantum dot is not particularly limited as long as it is a form used in the related art. For example, a quantum dot may have a spherical shape, a pyramidal shape, a multi-arm shape, or a cubic shape, or the quantum dot may be in the form of nanoparticles, nanotubes, nanowires, nanofibers, nanoplatelets, etc.

The quantum dot may control the color of emitted light according to a particle size thereof, and thus the quantum dot may have various colors of emitted light such as blue, red, green, etc.

The light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include a quantum dot but may include the scatterers SP.

The scatterers SP may be inorganic particles. For example, the scatterers SP may include at least one of TiO₂, ZnO, Al₂O₃, SiO₂, or hollow silica. The scatterers SP may include any one of TiO₂, ZnO, Al₂O₃, SiO₂, or hollow silica, or may be a mixture of two or more materials selected from TiO₂, ZnO, Al₂O₃, SiO₂, and hollow silica.

The first light control unit CCP1, the second light control unit CCP2, and the third light control unit CCP3 may each include base resins BR1, BR2, and BR3 for dispersing the quantum dots QD1 and QD2 and the scatterers SP. In an embodiment, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3. The base resins BR1, BR2, and BR3 may each be a medium in which the quantum dots QD1 and QD2 and the scatterers SP are dispersed, and may be formed of various resin compositions, which may be generally referred to as a binder. For example, the base resins BR1, BR2, and BR3 may be an acrylic-based resin, a urethane-based resin, a silicone-based resin, an epoxy-based resin, etc. The base resins BR1, BR2, and BR3 may each be a transparent resin. In an embodiment, the first base resin BR1, the second base resin BR2, and the third base resin BR3 may each be the same as or different from each other.

The light control layer CCL may include a barrier layer BFL1. The barrier layer BFL1 may prevent moisture and/or oxygen (hereinafter referred to as “moisture/oxygen”) from being introduced. The barrier layer BFL1 may prevent the light control units CCP1, CCP2, and CCP3 from being exposed to moisture/oxygen. The barrier layer BFL1 may cover the light control units CCP1, CCP2, and CCP3. A barrier layer BFL2 may be provided between the light control units CCP1, CCP2, and CCP3 and the color filter layer CFL.

The barrier layers BFL1 and BFL2 may include at least one inorganic layer. For example, the barrier layers BFL1 and BFL2 may each include an inorganic material. For example, the barrier layers BFL1 and BFL2 may each independently include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film in which light transmittance is secured, etc. The barrier layers BFL1 and BFL2 may each further include an organic film. The barrier layers BFL1 and BFL2 may be formed of a single layer or of multiple layers.

In the display device of an embodiment, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. The filters CF1, CF2, and CF3 may each include a polymer photosensitive resin, a pigment, or a dye. The first filter CF1 may include a red pigment or a red dye, the second filter CF2 may include a green pigment or a green dye, and the third filter CF3 may include a blue pigment or a blue dye. However, embodiments are not limited thereto, and the third filter CF3 may not include a pigment or a dye. The third filter CF3 may include a polymer photosensitive resin, but may not include a pigment or a dye. The third filter CF3 may be transparent. The third filter CF3 may be formed of a transparent photosensitive resin.

In an embodiment, the first filter CF1 and the second filter CF2 may each be yellow filters. The first filter CF1 and the second filter CF2 may not be separated from each other and may be provided as a single body. The first to third filters CF1, CF2, and CF3 may be disposed corresponding to the red light emitting region PXA-R, the green light emitting region PXA-G, and the blue light emitting region PXA-B, respectively.

A base substrate BL may be disposed on the color filter layer CFL. The base substrate BL may provide a base surface on which the color filter layer CFL and the light control layer CCL are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

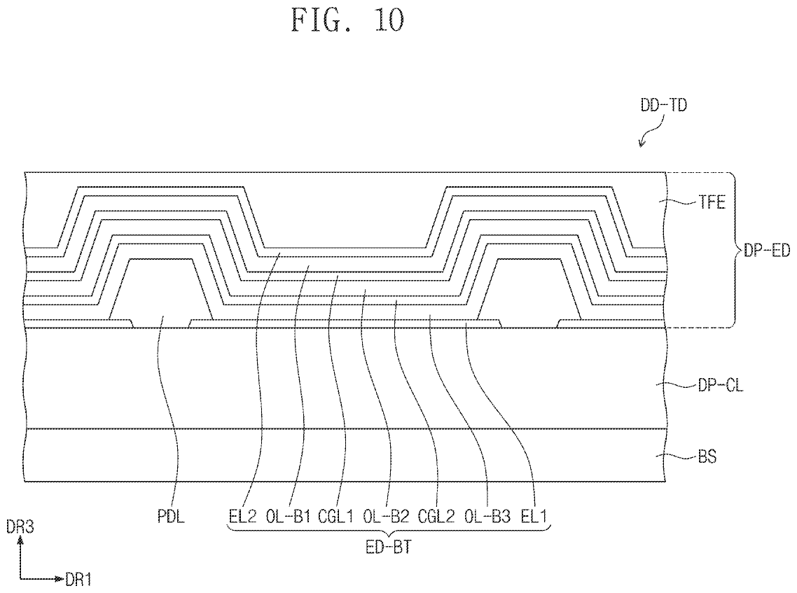

FIG. 10 is a schematic cross-sectional view showing a portion of a display device according to an embodiment. FIG. 10 shows a schematic cross-sectional view of a portion corresponding to the display panel DP of FIG. 9. In a display device DD-TD of an embodiment, a light emitting element ED-BT may include light emitting structures OL-B1, OL-B2, and OL-B3. The light emitting element ED-BT may include a first electrode EL1 and a second electrode EL2 facing each other, and the light emitting structures OL-B1, OL-B2, and OL-B3 stacked in a thickness direction between the first electrode EL1 and the second electrode EL2. The light emitting structures OL-B1, OL-B2, and OL-B3 each may include the emission layer EML (FIG. 9), a hole transport region HTR and an electron transport region ETR disposed with the emission layer EML (FIG. 9) therebetween. For example, the light emitting element ED-BT included in the display device DD-TD of an embodiment may be a light emitting element having a tandem structure including multiple emission layers.

In an embodiment illustrated in FIG. 10, light emitted from each of the light emitting structures OL-B1, OL-B2, and OL-B3 may all be blue light. However, embodiments are not limited thereto, and wavelength ranges of light emitted from each of the light emitting structures OL-B1, OL-B2, and OL-B3 may be different from each other. For example, the light emitting element ED-BT including the light emitting structures OL-B1, OL-B2, and OL-B3 emitting light in different wavelength ranges may emit white light.

Charge generation layers CGL1 and CGL2 may be disposed between neighboring light emitting structures OL-B1, OL-B2, and OL-B3. The charge generation layers CGL1 and CGL2 may each independently include a p-type charge generation layer and/or an n-type charge generation layer.

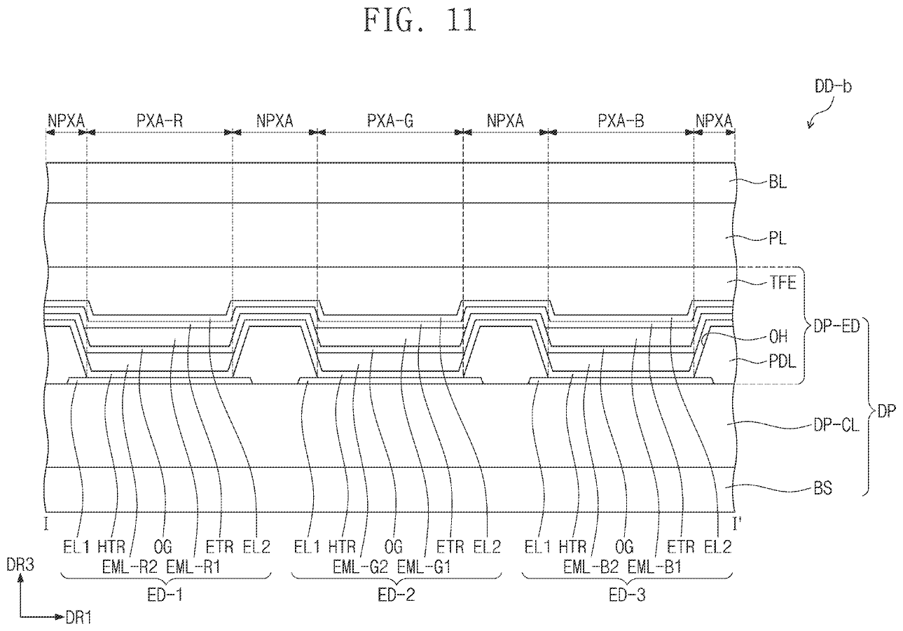

Referring to FIG. 11, a display device DD-b may include light emitting elements ED-1, ED-2, and ED-3 in which two emission layers are stacked. In comparison to FIG. 2, FIG. 11 illustrates that two emission layers are provided in each of the first to third light emitting elements ED-1, ED-2, and ED-3. In each of the first to third light emitting elements ED-1, ED-2, and ED-3, the two emission layers may emit light in a same wavelength range.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. A light emitting auxiliary portion OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The light emitting auxiliary portion OG may be a single layer or multiple layers. The light emitting auxiliary portion OG may include a charge generation layer. For example, the light emitting auxiliary portion OG may include an electron transport region, a charge generation layer, and a hole transport region that are sequentially stacked. The light emitting auxiliary portion OG may be provided as a common layer throughout the first to third light emitting elements ED-1, ED-2, and ED-3. However, embodiments are not limited thereto, and the light emitting auxiliary portion OG may be patterned inside the openings OH defined in the pixel defining films PDL and provided.

The first red emission layer EML-R1, the first green emission layer EML-G1, and the first blue emission layer EML-B1 may be disposed between the electron transport region ETR and the light emitting auxiliary portion OG. The second red emission layer EML-R2, the second green emission layer EML-G2, and the second blue emission layer EML-B2 may be disposed between the light emitting auxiliary portion OG and the hole transport region HTR.

For example, the first light emitting element ED-1 may include the first electrode EL1, the hole transport region HTR, the second red emission layer EML-R2, the light emitting auxiliary portion OG, the first red emission layer EML-R1, the electron transport region ETR, and the second electrode EL2, which are sequentially stacked. The second light emitting element ED-2 may include the first electrode EL1, the hole transport region HTR, the second green emission layer EML-G2, the light emitting auxiliary portion OG, the first green emission layer EML-G1, the electron transport region ETR, and the second electrode EL2, which are sequentially stacked. The third light emitting element ED-3 may include the first electrode EL1, the hole transport region HTR, the second blue emission layer EML-B2, the light emitting auxiliary portion OG, the first blue emission layer EML-B1, the electron transport region ETR, and the second electrode EL2, which are sequentially stacked.

An optical auxiliary layer PL may be disposed on the display element layer DP-ED. The optical auxiliary layer PL may include a polarizing layer. The optical auxiliary layer PL may be disposed on the display panel DP to control reflected light at the display panel DP from an external light. Although not shown in the drawings, in an embodiment, the optical auxiliary layer PL may be omitted from the display device DD-b.

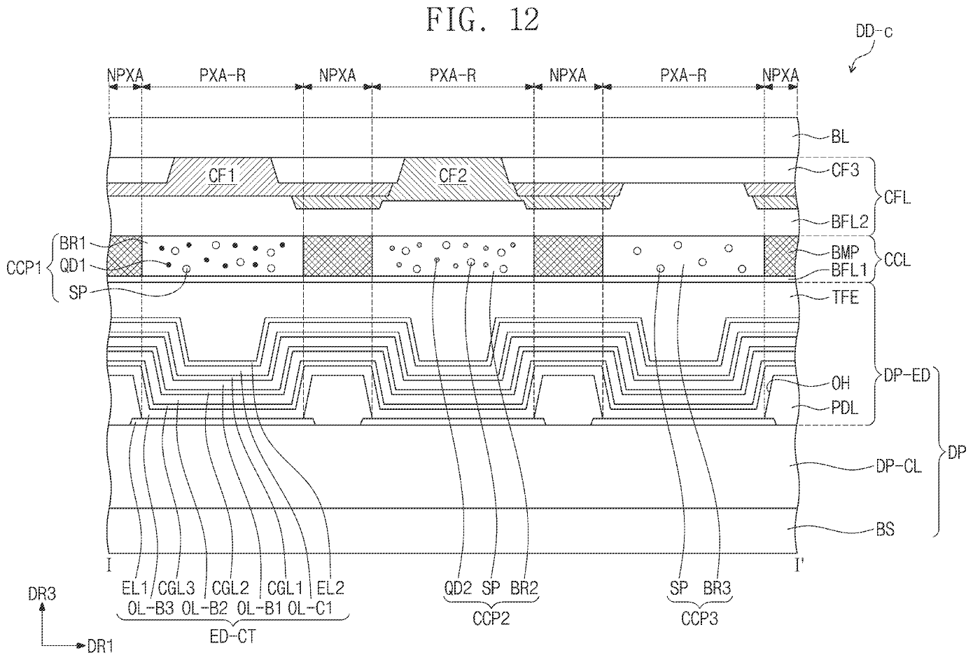

In comparison to FIGS. 9 and 10, the display device DD-c of FIG. 12 is illustrated to include four light emitting structures OL-B1, OL-B2, OL-B3, and OL-C1. The light emitting element ED-BT may include the first electrode EL1 and the second electrode EL2 facing each other, and the first to fourth light emitting structures L-B1, OL-B2, OL-B3, and OL-C1 stacked in a thickness direction between the first electrode EL1 and the second electrode EL2. Charge generation layers CGL1, CGL2, and CGL3 may be disposed between the first to fourth light emitting structures OL-B1, OL-B2, OL-B3, and OL-C1. Among the four light emitting structures, the first to third light emitting structures OL-B1, OL-B2, and OL-B3 may emit blue light, and the fourth light emitting structure OL-C1 may emit green light. However, embodiments are not limited thereto, and the first to fourth light emitting structures OL-B1, OL-B2, OL-B3, and OL-C1 may each emit light having different wavelength ranges.

A light emitting element according to an embodiment may include a first electrode, a second electrode disposed on the first electrode, and an emission layer disposed between the first electrode and the second electrode. The emission layer may include a hole transporting host, an electron transporting host, a phosphorescent sensitizer, and a fluorescent dopant. The light emitting element according to an embodiment may include a fluorescent dopant that emits light having a full width at half maximum (FWHM) equal to or less than about 20 nm. Light emitted by a fluorescent dopant having a small full width at half maximum may exhibit high color purity. Accordingly, the light emitting element according to an embodiment including the fluorescent dopant having a full width at half maximum equal to or less than about 20 nm may exhibit enhanced color purity.

The fluorescent dopant according to an embodiment may include a polycyclic aryl group in which three or more aryl groups are condensed in a pentacyclic condensed ring including at least one nitrogen atom and one boron atom as ring-forming atoms. The fluorescent dopant including the polycyclic aryl group in which three or more aryl groups are condensed may exhibit a characteristic of having a lower triplet state energy level than a singlet state energy level. Accordingly, the light emitting element including the fluorescent dopant according to an embodiment may exhibit long service life.

A light emitting element according to an embodiment includes a fluorescent dopant having a large difference between a singlet state energy level and a triplet state energy level, and may thus exhibit enhanced lifespan characteristics.

A light emitting element according to an embodiment includes a fluorescent dopant emitting light having a small full width at half maximum, and may thus exhibit enhanced color purity.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the following claims.

What is claimed is:

1. A light emitting element comprising:
a first electrode;
a second electrode disposed on the first electrode; and
an emission layer disposed between the first electrode and the second electrode, wherein
the emission layer includes:
a hole transporting host;
an electron transporting host;
a phosphorescent sensitizer; and
a fluorescent dopant, and
the fluorescent dopant emits light having a full width at half maximum (FWHM) equal to or less than about 20 nm.

2. The light emitting element of claim 1, wherein the fluorescent dopant has a difference in a range of about 0.4 eV to about 1.0 eV between a singlet state energy level and a triplet state energy level.

3. The light emitting element of claim 1, wherein the emission layer emits fluorescent light.

4. The light emitting element of claim 1, wherein the fluorescent dopant has an absolute value in a range of about 1.9 eV to about 2.2 eV of a triplet state energy level.

5. The light emitting element of claim 1, wherein the hole transporting host and the electron transporting host form an exciplex.

6. The light emitting element of claim 5, wherein
the exciplex has a greater triplet state energy level than the phosphorescent sensitizer, and
the phosphorescent sensitizer has a greater triplet state energy level than the fluorescent dopant.

7. The light emitting element of claim 1, wherein the fluorescent dopant comprises a compound represented by Formula 1: 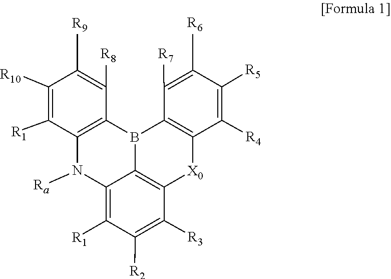
wherein in Formula 1,
X₀ is N(R_{b}) or S,
Rₐ and R_{b} are each independently a substituted or unsubstituted aryl group having 6 to 20 ring-forming carbon atoms,
R₁ to R₁₁ are each independently a hydrogen atom, a substituted or unsubstituted amine group, or a substituted or unsubstituted aryl group having 6 to 30 ring-forming carbon atoms, and
at least one of R₁ to R₁₁ includes a substituted or unsubstituted aryl group having 10 to 30 ring-forming carbon atoms.

8. The light emitting element of claim 1, wherein the fluorescent dopant is a multiple resonance (MR) type fluorescent dopant.

9. The light emitting element of claim 1, wherein the emission layer includes an amount of the fluorescent dopant in a range of about 0.4 vol % to about 0.8 vol %, with respect to a total volume of the hole transporting host, the electron transporting host, the phosphorescent sensitizer, and the fluorescent dopant.

10. The light emitting element of claim 1, further comprising:
a hole transport region disposed between the first electrode and the emission layer; and
an electron transport region disposed between the emission layer and the second electrode.

11. The light emitting element of claim 1, wherein the fluorescent dopant comprises one selected from Compound Group 1:

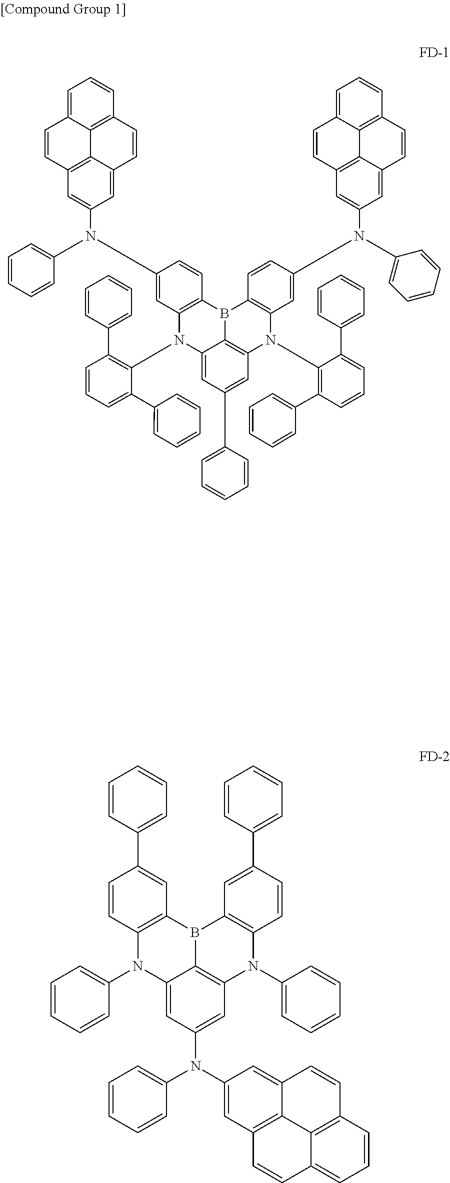 [SMILES: c1ccc(-c2cc3c4c(c2)N(c2c(-c5ccccc5)cccc2-c2ccccc2)c2cc(N(c5ccccc5)c5cc6ccc7cccc8ccc(c5)c6c78)ccc2B4c2ccc(N(c4ccccc4)c4cc5ccc6cccc7ccc(c4)c5c67)cc2N3c2c(-c3ccccc3)cccc2-c2ccccc2)cc1 ; c1ccc(-c2ccc3c(c2)B2c4cc(-c5ccccc5)ccc4N(c4ccccc4)c4cc(N(c5ccccc5)c5cc6ccc7cccc8ccc(c5)c6c78)cc(c42)N3c2ccccc2)cc1]

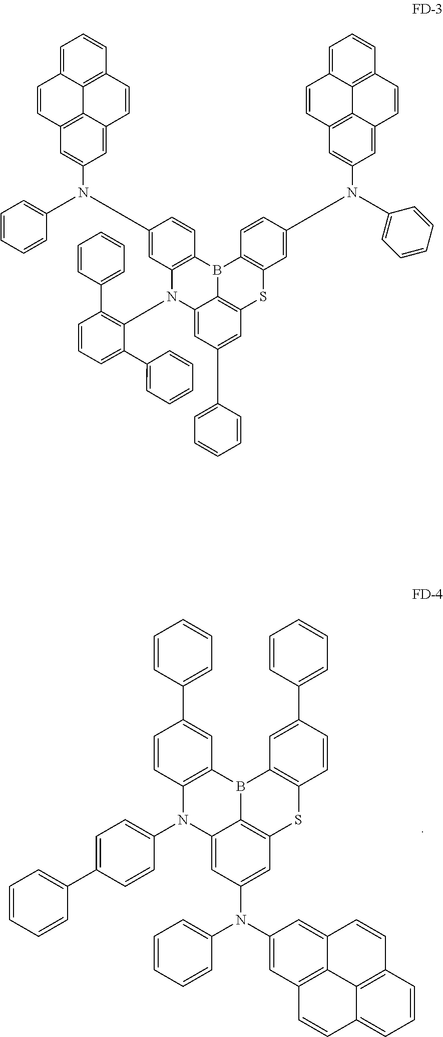 [SMILES: c1ccc(-c2cc3c4c(c2)N(c2c(-c5ccccc5)cccc2-c2ccccc2)c2cc(N(c5ccccc5)c5cc6ccc7cccc8ccc(c5)c6c78)ccc2B4c2ccc(N(c4ccccc4)c4cc5ccc6cccc7ccc(c4)c5c67)cc2S3)cc1 ; c1ccc(-c2ccc(N3c4ccc(-c5ccccc5)cc4B4c5cc(-c6ccccc6)ccc5Sc5cc(N(c6ccccc6)c6cc7ccc8cccc9ccc(c6)c7c89)cc3c54)cc2)cc1]

12. The light emitting element of claim 1, wherein the phosphorescent sensitizer comprises one selected from Compound Group 2:

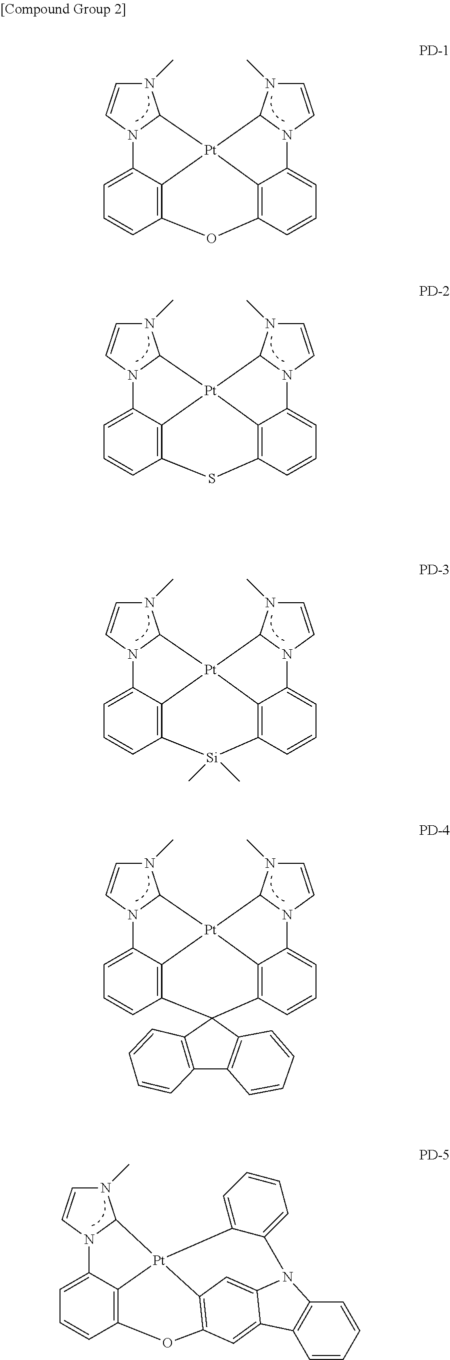

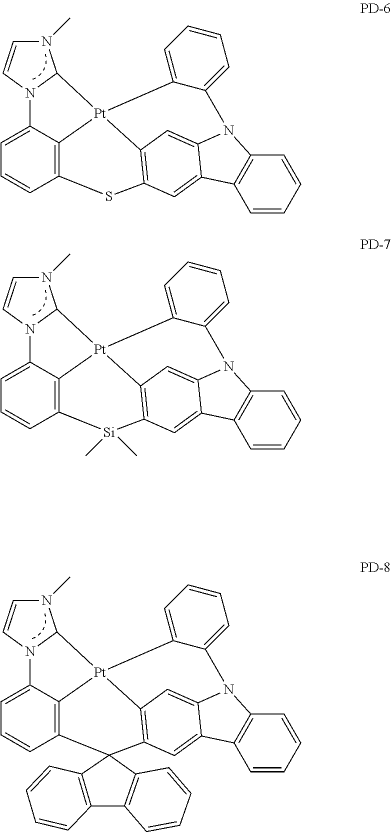

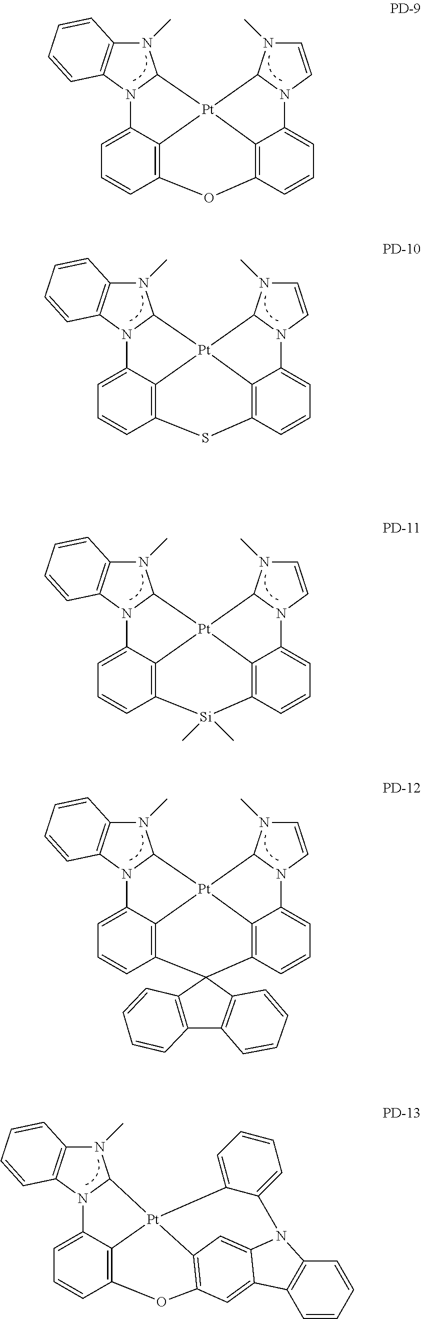

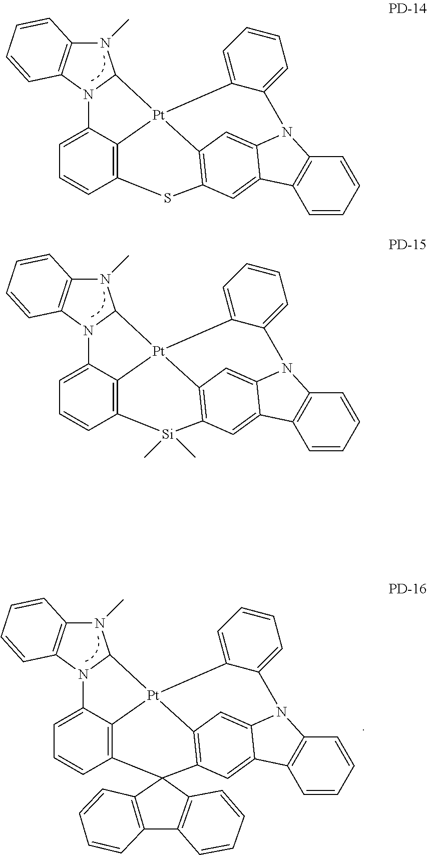

13. The light emitting element of claim 1, wherein the hole transporting host comprises one selected from Compound Group 3:

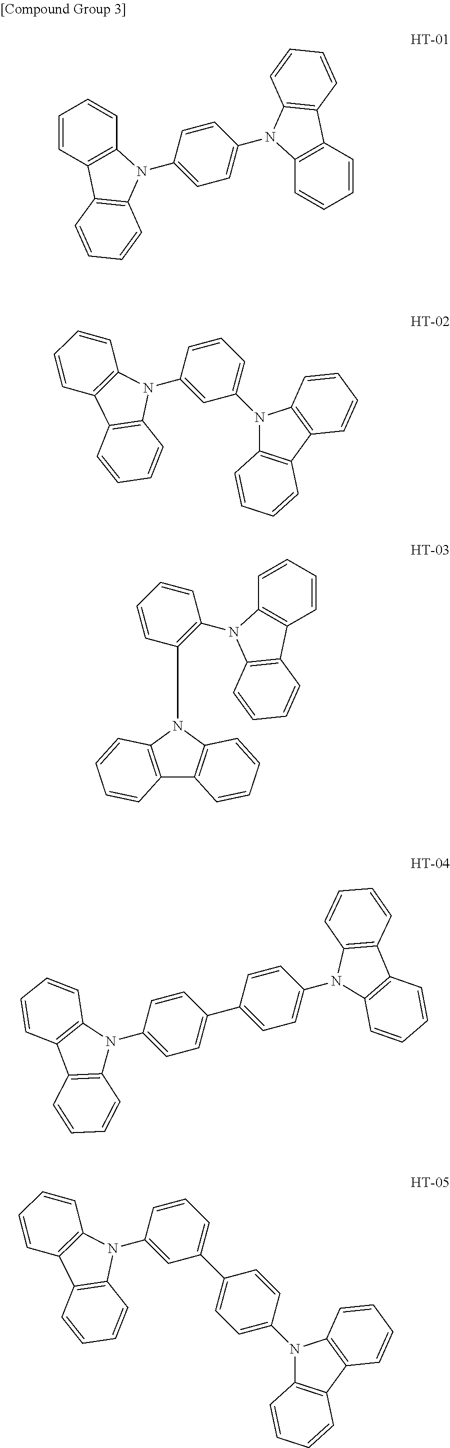

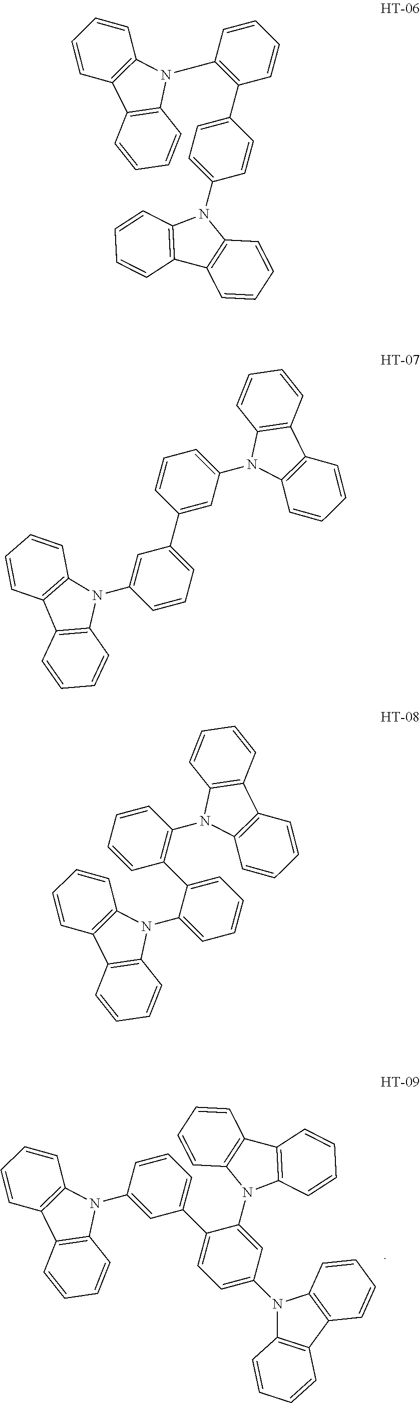 [SMILES: c1ccc(-n2c3ccccc3c3ccccc32)c(-c2ccc(-n3c4ccccc4c4ccccc43)cc2)c1 ; c1cc(-c2cccc(-n3c4ccccc4c4ccccc43)c2)cc(-n2c3ccccc3c3ccccc32)c1 ; c1ccc(-n2c3ccccc3c3ccccc32)c(-c2ccccc2-n2c3ccccc3c3ccccc32)c1 ; c1cc(-c2ccc(-n3c4ccccc4c4ccccc43)cc2-n2c3ccccc3c3ccccc32)cc(-n2c3ccccc3c3ccccc32)c1]

14. The light emitting element of claim 1, wherein the electron transporting host comprises one selected from Compound Group 4:

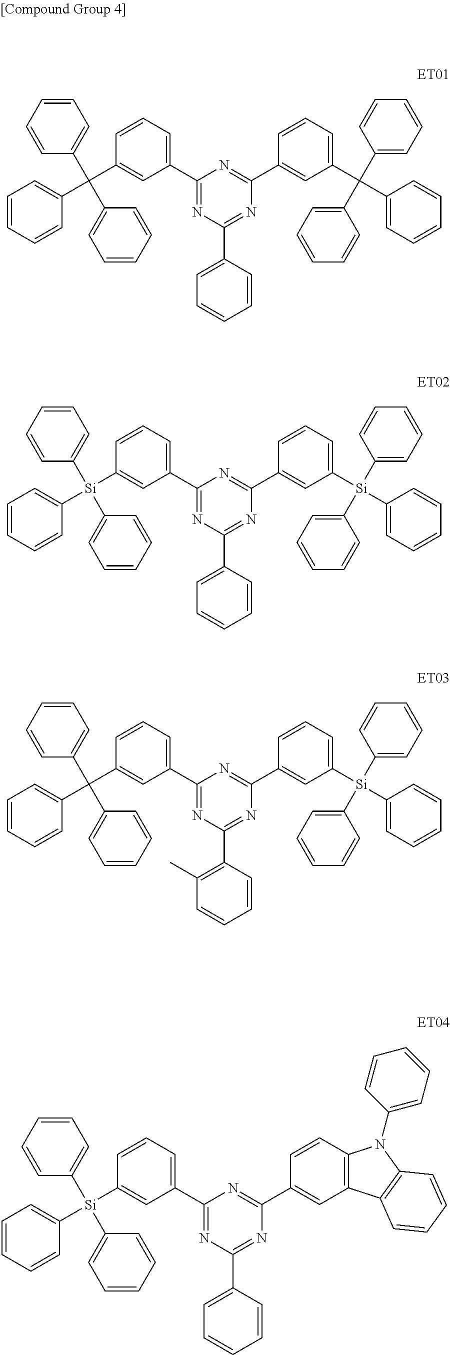 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc([Si](c3ccccc3)(c3ccccc3)c3ccccc3)c2)n1 ; c1ccc(-c2nc(-c3cccc([Si](c4ccccc4)(c4ccccc4)c4ccccc4)c3)nc(-c3ccc4c(c3)c3ccccc3n4-c3ccccc3)n2)cc1]

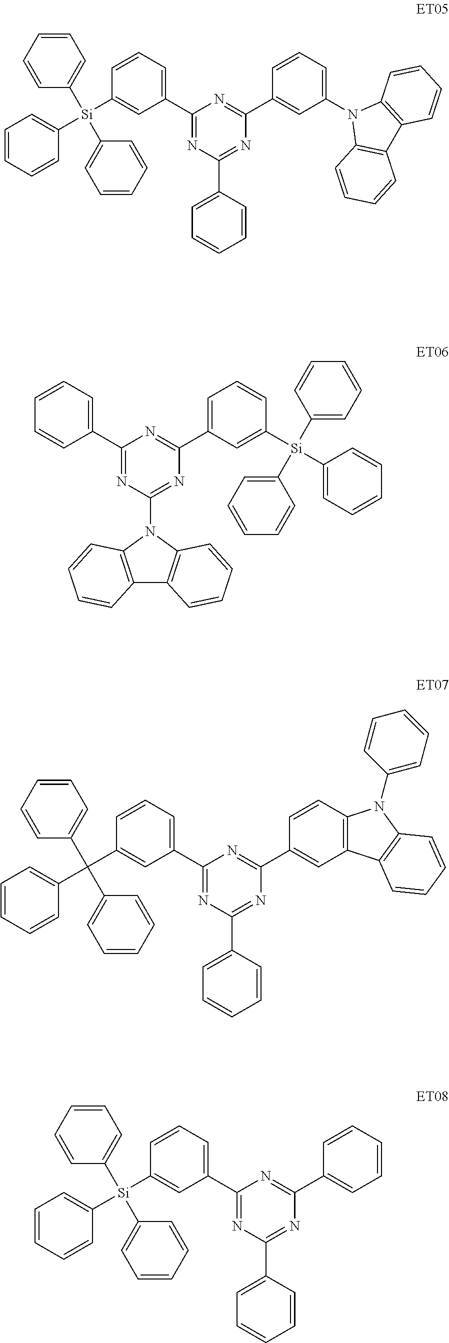 [SMILES: c1ccc(-c2nc(-c3cccc(-n4c5ccccc5c5ccccc54)c3)nc(-c3cccc([Si](c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-n3c4ccccc4c4ccccc43)n2)cc1 ; c1ccc(-c2nc(-c3cccc(C(c4ccccc4)(c4ccccc4)c4ccccc4)c3)nc(-c3ccc4c(c3)c3ccccc3n4-c3ccccc3)n2)cc1 ; c1ccc(-c2nc(-c3ccccc3)nc(-c3cccc([Si](c4ccccc4)(c4ccccc4)c4ccccc4)c3)n2)cc1]

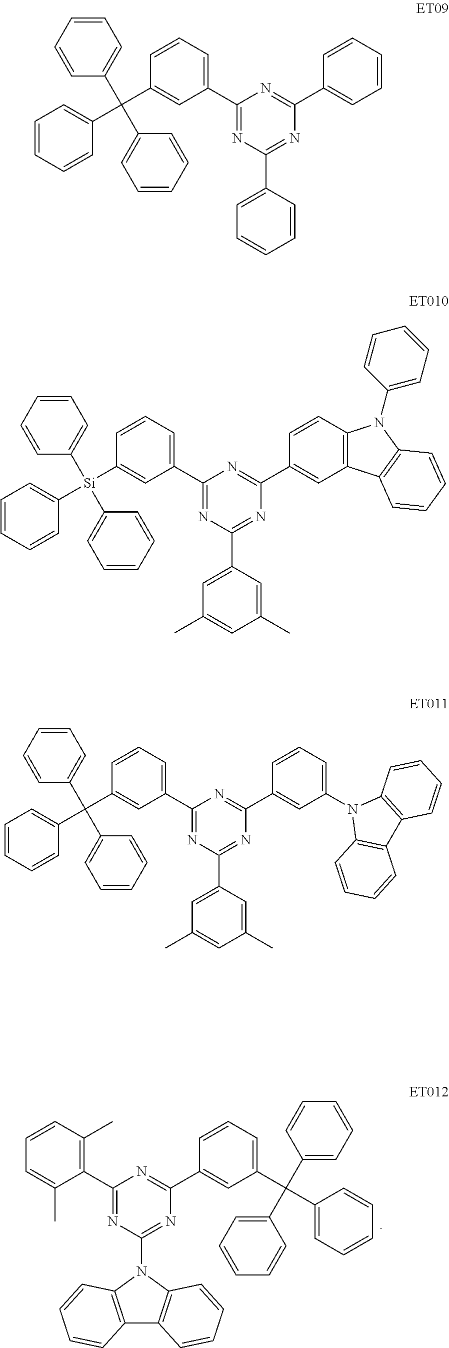 [SMILES: c1ccc(-c2nc(-c3ccccc3)nc(-c3cccc(C(c4ccccc4)(c4ccccc4)c4ccccc4)c3)n2)cc1 ; Cc1cc(C)cc(-c2nc(-c3cccc([Si](c4ccccc4)(c4ccccc4)c4ccccc4)c3)nc(-c3ccc4c(c3)c3ccccc3n4-c3ccccc3)n2)c1 ; Cc1cc(C)cc(-c2nc(-c3cccc(-n4c5ccccc5c5ccccc54)c3)nc(-c3cccc(C(c4ccccc4)(c4ccccc4)c4ccccc4)c3)n2)c1 ; Cc1cccc(C)c1-c1nc(-c2cccc(C(c3ccccc3)(c3ccccc3)c3ccccc3)c2)nc(-n2c3ccccc3c3ccccc32)n1]

15. A light emitting element comprising:
a first electrode;
a second electrode disposed on the first electrode; and
an emission layer disposed between the first electrode and the second electrode, wherein
the emission layer includes:
a hole transporting host;
an electron transporting host;
a phosphorescent sensitizer; and
a fluorescent dopant,
the fluorescent dopant emits light having a full width at half maximum (FWHM) equal to or less than about 20 nm, and
the fluorescent dopant includes a compound represented by Formula 1: 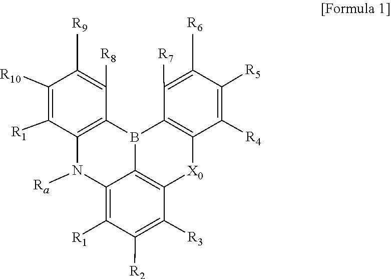
wherein in Formula 1,
X₀ is N(R_{b}) or S,
Rₐ and R_{b} are each independently a substituted or unsubstituted aryl group having 6 to 20 ring-forming carbon atoms,
R₁ to R₁₁ are each independently a hydrogen atom, a substituted or unsubstituted amine group, or a substituted or unsubstituted aryl group having 6 to 30 ring-forming carbon atoms, and
at least one of R₁ to R₁₁ includes a substituted or unsubstituted aryl group having 10 to 30 ring-forming carbon atoms.

16. The light emitting element of claim 15, wherein the fluorescent dopant has a difference in a range of about 0.4 eV to about 1.0 eV between a singlet state energy level and a triplet state energy level.

17. The light emitting element of claim 15, wherein
the hole transporting host and the electron transporting host form an exciplex,
the exciplex has a greater triplet state energy level than the phosphorescent sensitizer, and
the phosphorescent sensitizer has a greater triplet state energy level than the fluorescent dopant.

18. The light emitting element of claim 15, wherein the fluorescent dopant has an absolute value in a range of about 1.9 eV to about 2.2 eV of a triplet state energy level.

19. The light emitting element of claim 15, wherein the hole transporting host comprises a carbazole compound represented by Formula 2: 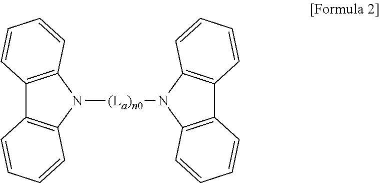
wherein in Formula 2,
n0 is 1 or 2, and
Lₐ is a substituted or unsubstituted arylene group having 6 to 20 ring-forming carbon atoms.

20. The light emitting element of claim 15, wherein the electron transporting host comprises a triazine compound represented by Formula 3: 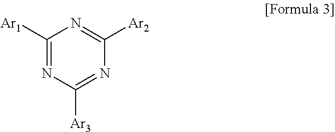
wherein in Formula 3,
Ar₁ to Ar₃ are each independently a substituted or unsubstituted aryl group having 6 to 20 ring-forming carbon atoms, or a substituted or unsubstituted heteroaryl group having 2 to 20 ring-forming carbon atoms.
